(19) United States
(12) Patent Application Publication
(10) Pub. No.: US 2023/0306152 A1
(43) Pub. Date: Sep. 28, 2023

(54) ANALYZING SYSTEMS OR GROUPS THAT UNDERGO CHANGES OVER TIME, AND RELATED DEVICES AND SYSTEMS

(71) Applicant: BATTELLE ENERGY ALLIANCE, LLC, Idaho Falls, ID (US)

(72) Inventor: Kevin L. Gering, Idaho Falls, ID (US)

(21) Appl. No.: 18/001,304

(22) PCT Filed: Jun. 23, 2021
(86) PCT No.: PCT/US2021/070762

§ 371 Date: Dec. 9, 2022

Related U.S. Application Data
(60) Provisional application No. 62/705,611, filed on Jul. 7, 2020.

(51) Int. Cl. G06F 30/20

(52) U.S. Cl. CPC G06F 30/20

(57) ABSTRACT

Embodiments disclosed herein include a method of analyzing changes in a system that occur over time. A battery is an example of such a system. The changes may result from discrete interactions. The method may include defining an electrode of a battery. The method may also include obtaining an expression for discrete interactions between the electrode and one or more of a solvent, a salt component, and an event that affects the battery. The method may also include modeling the discrete interactions between the electrode and the one or more of the solvent, the salt component, and the event. The method may also include obtaining, based on the modeling of the discrete interactions, an aging profile. The aging profile may be indicative of changes in the battery resulting from the discrete interactions.

### CROSS-REFERENCE TO RELATED APPLICATIONS

This application is a national phase entry under 35 U.S.C. § 371 of International Patent Application PCT/US2021/070762, filed Jun. 23, 2021, designating the United States of America and published as International Patent Publication WO 2022/011370 A1 on Jan. 13, 2022, which claims the benefit under Article 8 of the Patent Cooperation Treaty to U.S. Provisional Pat. Application Serial No. 62/705,611, filed Jul. 7, 2020, for “DETERMINING EFFECTS FROM TRANSIENT ACTIVE AGENTS AND TRANSIENT EVENTS UPON STATIC OR SEMI-STATIC POPULATIONS,” the entire disclosure of which is hereby incorporated herein by this reference.

### STATEMENT REGARDING FEDERALLY SPONSORED RESEARCH OR DEVELOPMENT

This invention was made with government support under Contract Number DE-AC07-05-ID14517 awarded by the United States Department of Energy. The government has certain rights in the invention.

### TECHNICAL FIELD

Embodiments of the present disclosure relate to analyzing devices, systems, and/or groups that may undergo changes over time, and more particularly, to a method, an apparatus, and a computer-readable medium for determining effects from transient active agents and transient events upon static or semi-static populations.

### BACKGROUND

Natural and man-made systems undergo interactions with their environment and through enacted duty cycles that result in diminished performance of one or more system members through one or more aging mechanisms. For a host of applications the exposure to aging-related conditions is based on transient events (TE) that create heightened stress on the system and/or transient active agents (TAA) that cause a reactive consequence with one or more static populations (SP) within the materials of the system. Herein, electrochemical batteries are used as a convenient example of a type of system that is prone to aging progression through TE and TAA. However, this disclosure is not limited to battery applications.

A battery converts stored chemical energy to electrical energy, which may be conveyed as a voltage potential. Rechargeable batteries may be charged and depleted multiple times. As a rechargeable battery ages, the storage capacity and conductance of the rechargeable battery may decrease (i.e., fade) between a Beginning of Life (BOL) and an End of Life (EOL). Over the service life of the rechargeable battery, certain performance characteristics may experience losses, such as capacity fade and power loss, among others.

There have been efforts to analyze battery aging. Among these efforts are those disclosed in U.S. Pat. No. 8,467,984, U.S. Pat. No. 8,346,495, U.S. Pat. No. 8,521,497, and U.S. Pat. No. 9,625,532. The disclosure of each of the foregoing documents is hereby incorporated herein by reference in its entirety.

### DISCLOSURE

Embodiments disclosed herein include a method of analyzing changes in a system that occur over time. The changes may result from discrete interactions. The method may include defining a population of a system. The method may also include obtaining an expression for discrete interactions between the population and one or both of an agent and an event. The method may also include modeling the discrete interactions between the population and the one or both of the agent and the event. The method may also include obtaining, based on the modeling of the discrete interactions, an aging profile. The aging profile may be indicative of changes in the population resulting from the discrete interactions.

Additional embodiments disclosed herein include a method of analyzing changes in a battery that occur over time. The changes may result from discrete interactions. The method may include defining an electrode of a battery. The method may also include obtaining an expression for discrete interactions between the population and one or more of a solvent, a salt component, and an event that affects the battery. The method may also include modeling the discrete interactions between the electrode and the one or more of a solvent, a salt component, and an event. The method may also include obtaining, based on the modeling of the discrete interactions, an aging profile. The aging profile may be indicative of changes in the battery resulting from the discrete interactions.

Additional embodiments are directed to one or more non-transitory computer-readable media that include instructions, that when executed by one or more processors, are configured to cause the one or more processors to perform operations. The operations may be for analyzing changes in a system that occur over time. The changes may result from discrete interactions. The operations may include defining a population of a system. The operations may also include obtaining an expression for discrete interactions between the population and one or both of an agent and an event. The operations may also include modeling the discrete interactions between the population and one or both of the agent and the event. The operations may also include obtaining, based on the modeling of the discrete interactions, an aging profile. The aging profile may be indicative of changes in the population resulting from the discrete interactions.

Additional embodiments are directed to one or more non-transitory computer-readable media that include instructions, that when executed by one or more processors, are configured to cause the one or more processors to perform operations. The operations may be for analyzing changes in a battery that occur over time. The changes may result from discrete interactions. The method may include defining an electrode of a battery. The operations may also include obtaining an expression for discrete interactions between the population and one or more of a solvent, a salt component, and an event that affects the battery. The operations may also include modeling the discrete interactions between the electrode and the one or more of a solvent, a salt component, and an event. The operations may also include obtaining, based on the modeling of the discrete interactions, an aging profile. The aging profile may be indicative of changes in the battery resulting from the discrete interactions.

### BRIEF DESCRIPTION OF THE DRAWINGS

FIGS. 1A, 1B, and 1C illustrate examples of common battery test data elements that could be used as aging metrics according to one or more embodiments.

FIG. 2 illustrates a combination of computational methods according to one or more embodiments.

FIGS. 3A and 3B illustrate examples of TAA-SP model predictions at 30° C. for remaining fraction of SP sites and unreacted TAA for TAA:SP = (a) 10:7, and (b) 2:7. (TAA mode 1) according to one or more embodiments.

FIG. 4 illustrates examples of TAA-SP model predictions at 30 and 50° C. for remaining fraction of SP sites and unreacted TAA for TAA:SP = 4:7. (TAA mode 1) according to one or more embodiments.

FIGS. 5A and 5B illustrate examples of TAA-SP model predictions at 30° C. for remaining fraction of SP sites and unreacted TAA for TAA:SP = 4:7, with SP particle fracturing at shown conditions. (TAA mode 1) according to one or more embodiments.

FIG. 6 illustrates results for single-sigmoid model (SSM) regression of TAA-SP model predictions at 30 and 50° C. (as from FIG. 4) for fractional loss (deactivation) of SP sites where TAA:SP = 4:7 according to one or more embodiments.

FIGS. 7A and 7B illustrate results for prediction of polarization effects through the polarization factor, considering various model parameters (see Eq. 19) according to one or more embodiments.

FIG. 8 illustrates results for prediction of secondary aging effects, considering various model parameters (see Eq. 20) according to one or more embodiments. Here, parameters c and d correspond to terms λ_{3D} and Δλ_{3D} in Eq. 20.

FIGS. 9A and 9B illustrate results for single-sigmoid model (SSM) regression of capacity loss and TAA-SP model predictions of capacity loss for an example secondary aging mechanism according to one or more embodiments.

FIG. 10 illustrates results for using TAA-SP model predictions at 30° C. to describe a two-mechanism aging process for lithium-ion batteries involving loss of lithium inventory (LLI) and loss of active host materials (LAM) according to one or more embodiments.

FIG. 11 illustrates results for using TAA-SP model predictions at 30° C. to describe a three-mechanism aging process for lithium-ion batteries involving primary aging (LLI), secondary aging (LAM), polarization and SP particle fracturing according to one or more embodiments.

FIG. 12 illustrates example results for TAA-SP model predictions under Mode 2, where a small amount of TAA is introduced with each TAA cycle (whereupon it is completely or partially consumed with successive cycles) according to one or more embodiments.

FIG. 13 illustrates results for TAA-SP model predictions under Mode 2 for the case of platinum oxidation at various temperatures according to one or more embodiments. Shown are the oxygen (TAA) breakthrough curves.

FIG. 14 illustrates results of testing versus TAA/SP results for Li-ion cells 4, 5 and 6.

FIG. 15 illustrates results of TAA/SP analysis of cycle component-wise aging for cell 4.

FIG. 16 illustrates results of TAA/SP analysis of cell aging under various cycling conditions.

FIGS. 17A and 17B illustrate results of a comparison of TAA/SP analyses to lab data for two different cycling conditions: 4C CCCV vs 6C CCCV.

FIG. 18 illustrates results of a comparison of TAA/SP analyses for various multistep charge conditions.

FIG. 19 is a flowchart illustrating an example method according to one or more embodiments.

FIG. 20 is a flowchart illustrating another example method according to one or more embodiments.

FIG. 21 is a functional block diagram illustrating an example device that may be used to implement various functions, operations, acts, processes, and/or methods, in accordance with one or more embodiments

### DETAILED DESCRIPTION

In the following detailed description, reference is made to the accompanying drawings, which form a part hereof, and in which are shown, by way of illustration, specific embodiments of the disclosure that may be practiced. These embodiments are described in sufficient detail to enable those of ordinary skill in the art to practice the disclosure, and it is to be understood that other embodiments may be utilized, and that structural, logical, and electrical changes may be made within the scope of the disclosure.

In this description, specific implementations are shown and described only as examples and should not be construed as the only way to implement the present disclosure unless specified otherwise herein. It will be readily apparent to one of ordinary skill in the art that the various embodiments of the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Referring in general to the following description and accompanying drawings, various embodiments of the present disclosure are illustrated to show their structure and method of operation. Common elements of the illustrated embodiments may be designated with similar reference numerals. It should be understood that the figures presented are not meant to be illustrative of actual views of any particular portion of the actual structure or method, but are merely idealized representations employed to more clearly and fully depict the present disclosure defined by the claims below.

It should be appreciated and understood that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal for clarity of presentation and description. It will be understood by a person of ordinary skill in the art that the signal may represent a bus of signals, wherein the bus may have a variety of bit widths and the embodiments of the present disclosure may be implemented on any number of data signals including a single data signal.

It should be further appreciated and understood that the various illustrative logical blocks, modules, circuits, and algorithm acts described in connection with embodiments disclosed herein may be implemented as electronic hardware, computer software, or combinations of both. To clearly illustrate this interchangeability of hardware and software, various illustrative components, blocks, modules, circuits, and steps are described generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the embodiments of the disclosure described herein.

The various illustrative logical blocks, modules, and circuits described in connection with the embodiments disclosed herein may be implemented or performed with a general-purpose processor, a special-purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor may be a microprocessor, but in the alternative, the general-processor may be any conventional processor, controller, microcontroller, or state machine. A general-purpose processor may be considered a special-purpose processor while the general-purpose processor executes instructions (e.g., software code) stored on a computer-readable medium. A processor may also be implemented as a combination of computing devices, such as a combination of a DSP and a microprocessor, a plurality of microprocessors, one or more microprocessors in conjunction with a DSP core, or any other such configuration.

When executed as firmware or software, the instructions for performing the processes described herein may be stored on a computer-readable medium. A computer-readable medium includes, but is not limited to, non-transitory storage media, such as magnetic and optical storage devices such as disk drives, magnetic tape, CDs (compact disks), DVDs (digital versatile discs or digital video discs), and semiconductor devices such as RAM, DRAM, ROM, EPROM, and Flash memory.

It should be understood that any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. Also, unless stated otherwise a set of elements may comprise one or more elements.

Systems and methods of the present disclosure may include and/or employ a method of direct statistical accounting for discrete interactions (e.g., between a population and agents and/or events). The accounting may include an accounting of ways in which the discrete interactions affect the population over time. In particular, the method may involve modeling how a population changes over time as the result of interactions in a complex system. More specifically, the method may involve modeling discrete interactions and the consequences of the discrete interactions on the population. In some embodiments, the population may be “static” or “semi-static.” The population being referred to as “static” or “semi-static” may mean that in some cases, the population is at a fixed initial amount in the system and does not change unless influenced by another agent or event through an interaction. The static population may be influenced by transient agents and/or transient events. The transient agents and/or events may occur at discrete times and may not persist. This method may include one or more improvements over an analytical approach for modeling aging of a system in that the magnitude and discrete timing of transient agents and/or events are allowed to vary over the time domain.

In the present disclosure, the term “system condition” includes conditions that are imposed upon an object that causes an effect on the performance or lifespan of the object. In other words, a system condition being imposed upon the object impacts the object (e.g., the aging of the object) and moves the object toward (or away from) its end of life by causing (or reversing) performance losses in the object through degradation (or improvement) mechanisms of the object. Such a system condition may include environmental conditions, operational conditions, and combinations thereof. A system condition is denoted herein as “i.” An arbitrary system condition, denoted herein as “i*,” is then a generalized statement of all system conditions that may contribute to the overall impacts (e.g., aging) of the object over a period of time. The arbitrary system condition (i*) may include one or more system conditions, and there may be many various and distinct arbitrary system conditions (i*) throughout the life of an object. For purposes of this disclosure, system condition (i) and arbitrary system condition (i*) may be used interchangeably. The arbitrary system condition (i*) may include unknown system conditions having unknown consequences. However, in many cases, the arbitrary system condition (i*) may include known system conditions, the consequences of which may also be unknown. In other words, an arbitrary system condition (i*) may include known or projected system conditions that have unknown consequences.

System conditions (i) may include environmental conditions, such as ambient temperature. System conditions (i) may also be characteristics relating to the use, condition, or other characteristic of the object itself. For batteries, system conditions (i) may include temperature, the state of charge (SOC) of the battery (i.e., the actual fraction of energy storage of the battery as a percentage of its fully charged state), and the usage cycle (i.e., electrochemically charging and discharging the battery and the percentage of time at rest). Active cycling of a battery may be referred to herein as a “cycle-life condition,” in that a substantial portion of the battery’s life experiences active cycling. Non-active cycling of a battery is referred to herein as a “calendar-life condition,” in that a substantial portion of the battery’s life is spent in a non-active (e.g., rest) state. The system conditions (i) may, at times, be variable over time. For example, a battery in a vehicle may experience seasonal changes in temperature over the course of the year. In some situations, a combination of a plurality of system conditions (i) (e.g., a variable combination of usage and rest periods as well as seasonal changes) may be experienced by an object.

In view of the various system conditions (i) that may be experienced by an object, at different times, and in different orders, defining an arbitrary system condition (i*) over object life may become complicated, if not unclear, and may be related to the path dependence of the aging process.

In the present disclosure İ_{int.} may describe an interaction rate. The interaction rate may describe a rate at which interactions occur between members of a system. The interaction rate may also describe a rate at which the interactions result in a change (that may be irreversible) of the population. For example, İ_{int.} may describe a rate of collision between an active site on an electrode and a solvent or salt component. The specifics of the interaction rate may depend on the system, object, or population to which the embodiments of the present disclosure are being applied. And, in the present disclosure İ_{int.}(i*) may describe an interaction rate for the arbitrary aging condition i*.

Although the context of embodiments of the present disclosure is described as generally applying to a battery, and in particular, a lithium-ion battery, the present disclosure is not to be viewed as so limited. For example, it is contemplated that the methodology described herein may be used in estimating aging consequences of arbitrary aging conditions (i*) for objects (even those outside the field of electronics or electrochemistry). Some examples of other fields to which the methods and embodiments of the present may apply include: devices, populations of living organisms, living organisms themselves, attributes among a population, and populations of molecules (e.g., a catalyst host) involved in a chemical reaction.

In the present disclosure, the term “aging” may include any changes that occur over time. These changes may include changes that degrade performance and/or improve performance. The changes may also include population growth or decrease irrespective of performance. For example, when a population is being described, aging may include growth or decline of the population.

An “object,” as defined herein, includes devices, systems, living organisms, populations of living organisms, and other items that may be described by an aging process, according to its own set of degradation mechanisms that are responsive to one or more known system conditions (i). One or more known system conditions (i) may be used to generate baseline aging characteristics, from which unknown consequences to arbitrary system conditions (i*) may be estimated. For example, embodiments of the present disclosure may be employed to estimate aging consequences of arbitrary system conditions (i*) for batteries, natural terrestrial systems, machines, biological systems, human health conditions, populations, etc., that may undergo aging subject to interactions between transient active agents, and/or transient events and static and/or semi-static populations, especially when the interactions can be described in terms of an interaction rate.

In the present disclosure, the term “battery” includes at least one cell that produces electric energy. In some embodiments, a battery may include rechargeable cells, fuel cells, and other cells that use an electrochemical reaction to produce electric energy, and combinations thereof. In addition, although batteries having lithium ion cells are primarily discussed herein, other types of batteries may be used and analyzed according to embodiments of the present disclosure.

One or more embodiments of the present disclosure may be used to diagnose and/or predict consequences of changes over time. For example, an aging profile of an object may be created. The aging profile may indicate relationships between the consequences (e.g., a state of the object between its beginning of life and its end of life) and one or more of the system conditions.

An example contemplated operation of the methods and systems of the present disclosure is described here. A system may be defined. Defining the system may include defining a population (e.g., a static population). Defining the population may include defining what makes up the population (e.g., what molecules, materials, organisms, etc., make up the population). Defining the population may also include defining ratios or amounts of the population. Defining the system may also include defining the environment of the population, including defining what interactions may occur between the population and agents and/or events. Defining the system may also include defining transient agents and/or transient events that may interact with the population. In some embodiments, defining the environment may include defining a cycle, which may include a definition of discrete interactions and/or a relationship between the interactions and time. Defining the environment may, additionally or alternatively, include defining other factors that may affect interactions, e.g., temperature, pressure (e.g., ambient air pressure), electrical current, etc.

As a specific example of defining a system, attributes that may be defined for a battery system are described here. Defining a battery system may include defining an electrode, which may include defining: molecular composition of the electrode, available surface sites (e.g., surface features that interact with TAA), surface sites accessible according to prevailing conditions (e.g., temperature and/or activation energy), molar concentration of sites, sensitivity toward TAA (reactivity), competing interactions between different TAA, and/or net sites deactivated over cumulative interactive cycles with TAA. Additionally, defining the battery system may include defining the TAA, e.g., the solvent of the battery system, which may include defining: molecular composition of the solvent, concentration of various molecules in the solvent, etc. Additionally, defining the battery system may include defining events that may affect the battery (e.g., TEs). Defining TEs may include defining: electrode solid particle cracking events (including, e.g., results of cracking events and rates of occurrence of cracking events). Additionally, defining the battery system may include defining the other factors that may affect the battery, which may include defining: charging time, discharging time, and charging current.

Continuing the description of the example contemplated operations, expressions for the interaction may be obtained. Specifically, expressions defining discrete interactions may be obtained. The expressions may include expressions for rates of interactions with regard to time. Additionally or alternatively, the expressions may include rates of interactions that result in changes in the population. The expressions may include sigmoid-based rate expressions, e.g., as described below. In some embodiments, the interactions may include irreversible changes. In some embodiments, the interactions may be defined as having a molecular or atomic basis.

As a specific example of obtaining expressions for interactions, obtaining expressions for a battery system may include obtaining the sigmoid-based rate expressions described below (e.g., with reference to equation (16)) that reflect the net effective rate of one or more aging mechanisms.

Continuing the description of the example contemplated operations, discrete interactions between the population and the agents and/or events may be modeled. The modeling may include using the expressions to model one or more interactions. The modeling may be based on one or more of the equations (1)-(20) described here.

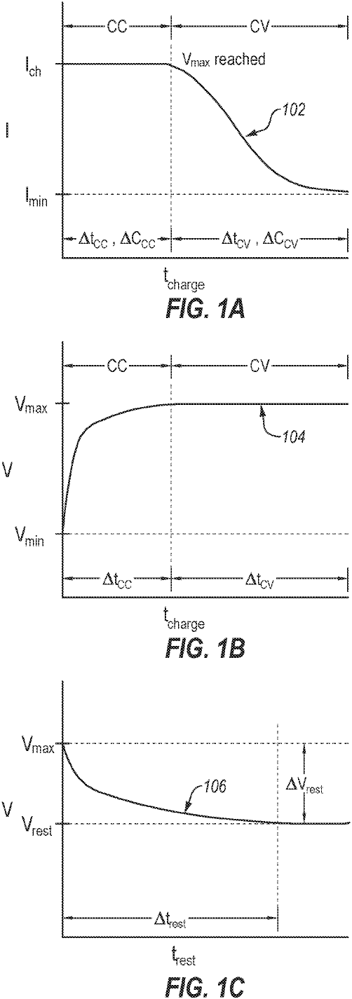

Continuing the description of the example contemplated operations, an aging profile may be obtained. The aging profile may be an output of the modeling. The aging profile may be indicative of changes in the population over time or over the interactions modeled. The aging profile may also be indicative of changes in integrity or stability of the materials in the system that are affected by the interactions. Integrity or stability of materials may be defined in terms of chemical, physical, mechanical, electrochemical, thermodynamic or other related metrics. Specific examples of aging profiles are given below with reference to FIGS. 1 through 13.

Continuing the description of the example contemplated operations, the system may be modeled various times using various populations, agents, events, and factors. The various models and/or aging profiles related to the various models may be compared to determine populations, agents, events, and/or factors that may improve the system (e.g., improve lifespan or effectiveness of the system). Determinations made based on the various models and/or aging profiles may be used to improve designs of systems and/or change how the systems are used or managed to improve lifespans of the systems.

Additionally or alternatively, an aging profile may be used to predict a lifespan of a system that has been designed. Predicting a lifespan based on modeling discrete interactions may be faster than an analytical method of determining a lifespan of a system, which may take a duration equal to the lifespan of the system to determine.

Additionally or alternatively, an aging profile of a system that has been used may be used to diagnose aging mechanisms affecting a system that has been used. For example, a used system may be modeled and have an aging profile generated, e.g., based on conditions during which the system was used. Then, based on conditions in which the system was used, correlative information can be asserted on how the aging mechanisms might progress under new or different conditions (e.g., under different conditions than it was used previously).

Additionally or alternatively, an aging profile of a system that has been used may be used to predict a remaining lifespan of a system that has been used. For example, a used system may be modeled and have an aging profile generated, e.g., based on conditions during which the system was used. Then, based on conditions in which the system may be used in the future, a second aging profile may be generated that may indicate how the used system may perform in the future (e.g., under different conditions than it was used previously).

Thus, the systems and method of the present disclosure may be useful in predicting performance, improving performance, supporting aging diagnostics, and/or designing an object. As an example, the aging profile of the object may be used to predict how the object will change over time, e.g., under assumed system conditions. As another example, the aging profile may be used to determine how the object has aged over its life based on information about the system conditions. As another example, the aging profile may be used to inform a user how the object can be used to improve the life of the object, e.g., by indicating system conditions that may increase a lifespan of the object. As another example, the aging profile may be used in a design process to optimize the design of the object. For example, one or more aging profiles of an object being designed may be created and the object may be improved according to the one or more aging profiles. As a specific example, one or more materials of the object may be chosen based on a comparison of aging profiles.

As an example to illustrate the systems and methods of the present disclosure, the systems and methods of the present disclosure may be applied to systems involving chemical interactions. For example, materials science is often defined by multiple coexisting phases that interact with each other, such as solid (S), liquid (L) and gas (G). These interactions can invoke a temporary or permanent effect within the material phases. However, other influencing agents can produce or promote an interactive effect within the phases, such as the passage of electrical current, magnetic and gravitational fields, thermal energy, or the presence of light. Analogues exist where one or more material phases are replaced with a responsive population, such as a biological organism (e.g., an animal or human) population responding to various influencing agents.

There are fields of endeavor that would benefit from diagnostic and predictive analyses of material/system/product lifecycles. An example is battery manufacturers and battery end-users. The unmet need is to know how a system will age in the actual application it is placed in. In terms of batteries, without clear knowledge on the aging process, there is undue risk to place batteries in new applications, which stalls investment in battery energy storage.

Using battery systems as an example, the battery industry is rapidly growing and comprises a large potential presence in the world-wide economy. Battery adoption is stalled by central issues of safety and longevity (e.g., over questions such as whether a battery will outlast the warranty in new applications), not to mention the aspect of battery cost. Battery manufacturers and end-users do not want to take on excessive risk.

Various embodiments disclosed herein include a physics-based platform to assess the cause-and-effect relationships between system stress factors and system aging. A battery modeling platform, e.g., the CellSage platform developed at Idaho National Laboratory, is an example of such a physics-based tool, and systems and methods of the present disclosure may be used with the CellSage platform. In practice, the systems and methods of the present disclosure provide explicit consideration of the chief factors tied to periodic transient events that impact battery stability and life in terms of the battery materials, battery design and arbitrary operating conditions. This creates increased knowledge of cause-and-effect on system aging and how the modeling framework can support optimization of design and use conditions. The systems and methods of the present disclosure can be used as an independent yet complementary route to existing physics-based tools (e.g., CellSage tools) to diagnose and predict aging processes in battery and non-battery applications. Other forms comprise an integration of the systems and methods of this disclosure within the larger physics-based architecture (e.g., the CellSage architecture), and can support machine learning (ML) of complex aging processes.

The modeling approach in the systems and methods of the present disclosure is computationally very fast, owing to direct analytical mathematical solutions, and it gives insights into how chosen materials and conditions of use give rise to degradation mechanisms. It is also robust due to the numerous battery parameters and their combinations that can be considered. It also can support battery management actions to help batteries last longer.

Some systems and methods of the present disclosure describe how transient active agents (TAA) and transient events (TE) can influence the state of a static or semi-static population (SP) by interactions with the SP. Transient analyses allow investigation of distinct short-lived conditions (relative to the life of the SP) that might persist over hundreds or thousands of cycles, yet whose rate behavior (kinetics) for interaction with SP is unknown. Many cases of TAA/TE-SP interactions exist in natural and man-made systems, such as material involved in routine duty cycles (e.g., batteries, reactors, consumer products, etc.) as well as biological populations responding to periodic exposure to TAA and TE. Some systems and methods of the present disclosure provide a generalized framework to investigate consequences of TAA/TE-SP interactions and hence can support lifecycle analyses (diagnostic, predictive) of SP and products dependent thereon as well as optimization of systems containing TAA, TE, and SP. Additionally, some systems and methods of the present disclosure may be compatible with existing CellSage architecture.

A computational technique is disclosed that serves as a robust template for investigating numerous, diverse and seemingly unrelated phenomena regarding Transient Active Agents (TAA), transient events (TE) and Static or Semi-static Populations (SP). Complexity arises when the effects of TAA or TE on SP cause a change in SP that then can either attenuate or compound future interactive effects between TAA or TE and SP. There can be one or more differing TAA species acting upon one or more types of SP groups, and these groups can grow, diminish, become activated or deactivated in response to interactions with TAA. Likewise, there can be more than one type of TE acting upon SP at any time. Embodiments disclosed herein may be able to quantify the transition between the beginning and ending states of the SP. A beginning state of SP could be defined as healthy, pure, as-new, unaged, of a given quantifiable condition, or to the contrary: unhealthy, impure, aged, deactivated etc. The methods herein support statistical predictions on population dynamics and longevity and could be indispensable to data analytics and machine learning (DA&ML) by providing a physical or physics-based framework to guide and properly bound DA&ML. This will be denoted as physics-guided DA&ML or PG-DA&ML.

Some systems and methods of the present disclosure may be and/or include a stand-alone computational tool or an integrated component within a larger system. Integration of some systems and methods of the present disclosure may be had with but not limited to other computational models (electrochemical, chemical, atomic, thermodynamic, etc.) as well as those for statistical, machine learning, and data conditioning or archiving purposes. As such some systems and methods of the present disclosure may exchange information with other integrated parts or external parts. Integration of some embodiments disclosed herein may also be had with management systems that enact control actions based in part from information provided by the disclosure.

In some embodiments, a predictive framework is disclosed to determine how TAA and TE can influence the state of a SP by interactions with the SP. Transient analyses allow investigation of distinct short-lived conditions (relative to the life of the SP) that might persist over hundreds or thousands of cycles, yet whose rate behavior (kinetics) for interaction with SP is unknown. Many cases of TAA/TE-SP interactions exist in natural and man-made systems, such as material involved in routine duty cycles (e.g., batteries, reactors, consumer products, etc.) as well as biological populations responding to periodic exposure to TAA and TE. This method provides a generalized framework to investigate consequences of TAA/TE-SP interactions and hence can support lifecycle analyses (diagnostic, predictive) of SP and products dependent thereon as well as optimization of systems containing TAA, TE, and SP. This method is compatible with existing CellSage architecture.

In a system containing multiples of SP, TAA, or TE there may be interactions that cause aging artifacts that are non-linear (that is, non-additive from the simple single types of TAA etc.) or preferential in terms of rate and individual aging progression. As an example, a system in which a sub-population of SP “B” is lesser than the main SP population “A,” wherein B acts as a sacrificial population for early preferential interactions with TAA and TE in order to protect SP A. Similarly, a sacrificial TAA component “C” can provide early preferential interactions with SP to protect the non-C TAA population.

The following terms may be used to describe aspects of some embodiments and/or to describe bases for some embodiments or aspects thereof. For example, some of the following terms may describe aspects or derivatives of an expression for discrete interactions.

The term “surface area” may refer to the state of being or housing SP sites (e.g., for 2D surface interactions).

The term “material volume” may refer to the state of being or housing SP sites (e.g., for 3D volume interactions).

The term “available surface sites” may refer to SP (e.g., surface features that interact with TAA), accessible according to prevailing conditions including, for example: temperature, activation energy, molar concentration of sites, sensitivity toward TAA (e.g., reactivity), competing interactions between different TAA, net sites deactivated over cumulative interactive cycles with TAA, etc.

A decrease of SP may be due to loss of active/available surface area.

A growth of SP may be due to surface area growth from solid particle cracking or “birth” of new SP due to conversion or activation processes. Cracking, conversion and activation are examples of TE at conditions that differ from a baseline condition.
“j” is the TAA interaction cycle index
“k” describes a sub-interval of a cycle and “K” describes a full cycle
“m” describes a TAA of a number of TAAs that may interact with an SP during a life of an object
“n” describes a TE of a number of TEs that may interact with an SP during a life of an object
i* is the arbitrary system condition wherein aging stress factors are described.
θⱼ(i*) is the fraction of remaining unconverted SP sites at cycle j at i*.

$${N}_{S P s i t e s}^{o}$$
is the number of initial available SP sites, generally within a reference area or volume, at reference conditions of interest (e.g., reference temperature).
N_{SP} ₛᵢₜₑₛ(i*) is the number of initial available SP sites, generally within a reference area or volume, at arbitrary system conditions of interest (e.g., non-reference temperature, etc.).
Δtⱼ is the time interval that spans each j cycle (can vary over j)
Δtₙₒₙ₋ⱼ is the time interval between each successive j cycle (can vary over j)
İ_{int.}(i*) is the average interaction rate between TAA and a single SP member over Δtⱼ
Δt is the standard time interval (second, minute, hour, day, or week, etc.)
rᵢₙₜ is the rate of TAA-SP interactions under the prevailing conditions present during Δtⱼ.
rₙₒₙ₋ᵢₙₜ is the rate of TAA-SP interactions under the prevailing conditions present during Δtₙₒₙ₋ⱼ.
nⱼ is the number of Δtⱼ cycles that occur over each Δt.
nₙₒₙ₋ⱼ is the number of Δtₙₒₙ₋ⱼ cycles that occur over each Δt.

Some methods allow for interconversion between domains (e.g., time and j cycle number).

### Mathematical Framework

A change in SP sites that occurs in the first TAA cycle (j = 1) may first be considered. This is described by the general definition of the θⱼ term at system conditions i* and time interval Δtⱼ:

$${θ}_{j = 1} \left(\text{i*}\right) = \frac{{N}_{S P s i t e s , j = 1} \left(\text{i*}\right)}{{N}_{S P s i t e s}^{o} \left(\text{i*}\right)} \qquad \text{(1)}$$

then

$${α}_{j = 1} \left(\text{i*}\right) = \text{Δ} {N}_{S P s i t e s , j = 1} \left(\text{i*}\right) = {N}_{S P s i t e s}^{o} \left(1 - {θ}_{j = 1} \left(\text{i*}\right)\right) \qquad \text{(2)}$$

and for the second j cycle

$${θ}_{j = 2} \left(\text{i*}\right) = \frac{{N}_{S P s i t e s , j = 2} \left(\text{i*}\right)}{{N}_{S P s i t e s}^{o}} \qquad \text{(3)}$$

$$\begin{matrix}{α}_{j = 2} \left(\text{i*}\right) = \\ \text{Δ} {N}_{S P s i t e s , j = 1} \left(\text{i*}\right) + \text{Δ} {N}_{S P s i t e s , j = 2} \left(\text{i*}\right) = {N}_{S P s i t e s}^{o} \left(1 - {θ}_{j = 2} \left(\text{i*}\right)\right)\end{matrix} \qquad \text{(4)}$$

and so on for multiple j cycles.

The generalized expressions are derived as

$${θ}_{j} \left(\text{i*}\right) = \frac{{N}_{S P s i t e s} \left(\text{i*}\right) - {β}_{j - 1} \left(\text{i*}\right)}{{N}_{S P s i t e s} \left(\text{i*}\right) + {α}_{j} \left(\text{i*}\right)} \qquad \text{(5)}$$

where

$${α}_{j} \left(\text{i*}\right) = {\sum }_{k = 1}^{K} {\dot{I}}_{i n t .} \left(k , \text{i*}\right) \text{Δ} {t}_{k} \qquad \text{(6)}$$

for a single pulse, and

$${β}_{j - 1} \left(\text{i*}\right) = {\sum }_{j = 1}^{j - 1} \left[{θ}_{j} \left(\text{i*}\right) {\sum }_{k = 1}^{K} {\dot{I}}_{i n t .} \left(k , \text{i*}\right) \text{Δ} {t}_{k}\right] \qquad \text{(7)}$$

αⱼ represents the total TAA/TE-SP interactions over Δtⱼ that result in a change in SP (i.e., that alters θⱼ(i*)). İ_{int.}(k, i*) is the rate of successful interactions between TAA/TE and SP during the k^{th} time interval that resulted in a change of state in SP. Note that for αⱼ (i*) and βⱼ₋₁ (i*) the k-to-K summand covers each entire j cycle duration time. Time subdivisions (1 to K) are denoted in cases where the transient behavior of TAA/TE to SP is sufficiently non-constant over a given cycle to warrant a summation. Given the relatively short duration of Δtⱼ (transient) compared to the entire aging process, it is typically assumed there is a single time subdivision such that k=1 only, wherein İ_{int.}(i*) then represents the average rate of interactions between TAA/TE and a SP over Δtⱼ, giving the simplified forms

$${α}_{j} \left(\text{i*}\right) = {\dot{I}}_{i n t .} \left(\text{i*}\right) \text{Δ} {t}_{j} \text{for a single j pulse} \qquad \text{(8)}$$

$${β}_{j - 1} \left(\text{i*}\right) = {\sum }_{j = 1}^{j - 1} \left[{θ}_{j} \left(\text{i*}\right) {\dot{I}}_{i n t .} \left(\text{i*}\right) \text{Δ} {t}_{j}\right] \qquad \text{(9)}$$

It is recognized that multiple TAA and TE can coincide within any particular Δtⱼ. This is represented by adding summations over TAA (“m” TAA types) and TE (“n” TE types) within the expression for αⱼ(i^{∗}) and βⱼ₋₁(i^{∗}) as follows:
A. For expression involving k-to-K time sub-intervals:
$${α}_{j} \left(\text{i*}\right) = {\sum }_{k = 1}^{K} \left[{\sum }_{m} {\sum }_{n} \left({\dot{I}}_{i n t .} \left(k , m , n , \text{i*}\right) \text{Δ} {t}_{k}\right)\right] \text{for a single j pulse} \qquad \text{(10)}$$
$${β}_{j - 1} \left(\text{i*}\right) = {\sum }_{j = 1}^{j - 1} \left[{θ}_{j} \left(\text{i*}\right) {\sum }_{k = 1}^{K} \left[{\sum }_{m} {\sum }_{n} \left({\dot{I}}_{i n t .} \left(k , m , n , \text{i*}\right) \text{Δ} {t}_{k}\right)\right]\right] \qquad \text{(11)}$$
B. For cases where k = 1
$${α}_{j} \left(m , n , \text{i*}\right) = {\sum }_{m} {\sum }_{n} \left({\dot{I}}_{i n t .} \left(m , n , \text{i*}\right) \text{Δ} {t}_{k}\right) \text{for a single j pulse} \qquad \text{(12)}$$
$${β}_{j - 1} \left(m , n , \text{i*}\right) = {\sum }_{j = 1}^{j - 1} \left[{θ}_{j} \left(\text{i*}\right) \left[{\sum }_{m} {\sum }_{n} \left({\dot{I}}_{i n t .} \left(m , n , \text{i*}\right) \text{Δ} {t}_{k}\right)\right]\right] \qquad \text{(13)}$$

As another point of distinction, i* conditions can change over the j index, allowing the interaction terms (İ_{int.}) to also be variable over j. This is seen, for example, if variance exists over aging time in temperature, state of the solid, cycling severity, introduction of new TAA or TE, etc. As another point of distinction, there can be more than one group of SP in a system, wherein the different SP subgroups can exhibit differing responses to TAA and TE. As such, the αⱼ and βⱼ₋₁ terms would be defined toward each SP subgroup at each j and i* (i.e., there would be five αⱼ and five βⱼ₋₁ terms if there are five SP subgroups). For the sake of demonstration, if “q” is used as the SP subgroup index, then the SP subgroup expressions for cases of k=1 are denoted as

$${α}_{j} \left(m , n , q , \text{i*}\right) = {\left[{\sum }_{m} {\sum }_{n} \left({\dot{I}}_{i n t .} \left(m , n , \text{i*}\right) \text{Δ} {t}_{k}\right)\right]}_{q} \text{for a single j pulse} \qquad \text{(14)}$$

$${β}_{j - 1} \left(m , n , q , \text{i*}\right) = {\left[{\sum }_{j = 1}^{j - 1} \left[{θ}_{j} \left(\text{i*}\right) \left[{\sum }_{m} {\sum }_{n} \left({\dot{I}}_{i n t .} \left(m , n , \text{i*}\right) \text{Δ} {t}_{k}\right)\right]\right]\right]}_{q} \qquad \text{(15)}$$

These expressions could also be rearranged to isolate particular combinations of TAAₘ, TEₙ and SP_{q} with resultant θⱼ(q,i*) that quantify deactivation or loss of each SP subgroup. In some embodiments, the expressions above and described points of distinction comprise an element to the generalized recursive framework for this method.

The interaction rate terms may be useful in describing and quantifying the interactive tendencies between TAA, TE and SP for particular scenarios. In practice, these rate terms will either follow established theories for interaction frequency (e.g., kinetic theory of gases), or can be posited as theoretical expressions whose validity can be verified through regression to actual data. It is therefore left to the practitioner to provide suitable expressions for the interactive rate terms that capture the physics of each particular application. One or more examples of this is given below. Interaction rate terms will reflect the rate behavior for distinct j and i* that occur over an aging simulation timeline. The approach herein allows two modes for TAA introduction to the system: Mode 1 - TAA has a fixed initial concentration that is not refreshed over time (batch reactor scenario). Mode 2 - A small amount of TAA is introduced with each TAA cycle, whereupon it is completely or partially consumed with successive cycles.

The method described above does not assume kinetic information about the interactive processes, such as an overall rate constant “a,” order of interaction (reaction) “b” and theoretical maximum extent of interaction (reaction) “M.” This can be obtained by combining the present approach with a sigmoid-based rate expression that contains the (a,b,M) terms, which can be written in terms of rate with respect to cycle number j or with respect to time. Given an aging mechanism “i” and the j cycle basis we impose the following equality (equivalency of normalized rates) to quantify aging of a given performance measure

$$\begin{matrix}ψ \left(i , \text{i*} , j\right) = \\ \left\{\left(1 - \text{θ} \text{j} \left(i , \text{i*}\right)\right) {=}^{!} {{M}^{′}}_{i} + 2 \left({M}_{i} - {{M}^{′}}_{i}\right) \left[\frac{1}{2} - \frac{1}{1 + e x p \left({\left({a}_{i} j\right)}^{{b}_{i}}\right)}\right]\right\} ,\end{matrix} \qquad \text{(16)}$$

where:
Ψ (i, i*,j) is an arbitrary battery-performance attribute that reflects an aging trend over time, such as fraction of capacity loss, conductance loss, power fade, etc. This term generally has a zero value at time zero unless
$${{M}^{′}}_{i}$$
is non-zero;
$${{M}^{′}}_{i}$$
is the value of the fractional extent of aging due to i* conditions at time zero (usually zero for a new system);
αᵢ is an equivalent intrinsic rate constant for mechanism i that affects aging due to i* conditions; and
bᵢ is an equivalent intrinsic kinetic order of such mechanism i.

Note that a and b terms can be obtained from regression analysis of either aging data or of outputs from the present method (via equation 16), and they reflect the influence of stress factors defined by the i* conditions. Interconversion to a time basis can be obtained by knowing how many j cycles transpire per unit time (e.g., day).

Considering as many as “Z” aging mechanisms, the above performance measure equality can be extended as

$$\begin{matrix}{\sum }_{i}^{Z} ψ \left(i , \text{i*} , j\right) = \left\{{\sum }_{i}^{Z} \left(1 - \text{θ} \text{j} \left(i , \text{i*}\right)\right) {=}^{!}\right) \\ \left({\sum }_{i}^{Z} \left({{M}^{′}}_{i} + 2 \left({M}_{i} - {{M}^{′}}_{i}\right) \left[\frac{1}{2} - \frac{1}{1 + e x p \left({\left({a}_{i} j\right)}^{{b}_{i}}\right)}\right]\right)\right\}\end{matrix} \qquad \text{(17)}$$

The above description focused on a static population for SP. However, there can be cases wherein the aging processes cause a dynamic consequence in SP under a “semi-static” condition. An example of this is when cracking of solid particles exposes more active SP sites. Such a dynamic can be expressed by a number of mathematical formulae. Herein the sigmoid rate basis is maintained:

$${N}_{S P s i t e s} \left(\text{i*} , j\right) = {N}_{S P s i t e s} \left(\text{i*}\right) \left(1 + 2 {{M}^{′}}_{S P} \left[\frac{1}{2} - \frac{1}{1 + e x p \left({\left({a}_{S P} j\right)}^{{b}_{S P}}\right)}\right]\right) , \qquad \text{(18)}$$

or similar form that allows both positive (gain) or negative (decline) change in N_{SP} ₛᵢₜₑₛ (i*,j) over j or time.

### Other Aging Processes Tied to Cycling Protocol

Aging processes are either reversible or irreversible. Irreversible mechanisms entail chemical reactions, mechanical degradation or other changes that cannot go back to a lesser-aged state without the input of considerable work to or by the system. Reversible mechanisms denote a temporary condition whereby system performance is diminished due to a disequilibrium (e.g., temporary chemical or temperature gradients) that will abate given sufficient rest time. Electrochemical cell polarization is one such example of a reversible loss, where the apparent capacity is diminished due to concentration polarization as the cell becomes polarized at a high current. If this is carried forward cycle-to-cycle, then polarization hysteresis can develop and continue to decrease capacity in a non-linear trend. An expression that describes the polarization effects on aging over j cycles is captured by a polarization factor

$${f}_{p o l} \left(\text{i*} , j\right) = {M}_{p o l} {\left(1 - {γ}_{p o l} {\left(1 + \text{Δ} {γ}_{p o l}\right)}^{j}\right)}^{j} , \qquad \text{(19)}$$

which predicts that polarization can have an ever-increasing impact due to the building hysteresis. The terms γₚₒₗ and Δγₚₒₗ are material parameters that reflect a system’s susceptibility to polarization, and Mₚₒₗ is the maximum theoretical extent of polarization possible at i* conditions, ranging from 0 (none) to 1 (complete). γₚₒₗ is the polarization increment that manifests during the first j cycle, while Δγₚₒₗ is the average or representative change in γₚₒₗ over successive cycles. In practice ƒₚₒₗ (i*,j) would be applied to the typical TAA/TE-SP or sigmoid rate expression results as gained for no polarization effects.

Aging processes involving solid materials can have differing mechanism that manifest on the surface of particles (2D) versus within the particles themselves (3D). While the previous development for TAA/TE-SP and sigmoidal rate expressions can be applied to both 2D and 3D considerations, an alternate 3D expression was developed that is based on a concept similar to that of polarization, that is, volume elements within solids that house SP that undergo aging will affect neighboring regions over time, causing an ever-increasing rate of aging until a thermodynamic or mechanical limit is reached. This is referred to as a secondary mechanism, since other surface-driven 2D aging mechanisms occur earlier in time and are hence called primary mechanisms.

$${f}_{2 \text{nd-ary}} \left(\text{i*} , j\right) = {M}_{3 D} \left(1 - {\left(1 - {λ}_{3 D} {\left(1 + Δ {λ}_{3 D}\right)}^{j}\right)}^{j}\right) \qquad \text{(20)}$$

The terms λ,_{3D} and Δλ_{3D} are material parameters that reflect a system’s susceptibility to SP degradation in the 3D space, and M_{3D} is the maximum theoretical extent of solid material degradation possible at i* conditions, ranging from 0 (none) to 1 (complete). λ_{3D} is the active material loss increment (3D basis) that manifests during the first j cycle, while Δλ_{3D} is the average or representative change in λ_{3D} over successive cycles. In practice ƒ_{2nd-ary} (i*,j) would be added to to the typical TAA/TE-SP or sigmoid rate expression results for primary mechanisms.

In practice, the parameters within the expressions for ƒₚₒₗ (i*,j) (equation (19)) and ƒ_{2nd-ary} (i*,j) (equation (20)) would be determined from well-designed lab testing that focused on early-life aging behavior covering a small number of j cycles. The collective mathematical treatment above covering TAA/TE-SP, polarization, and secondary mechanisms could be used to regress system aging data (whether early, mid or extended aging) to characterize and diagnose aging mechanisms, material response to stress factors, predict system life under non-test conditions, and optimize system parameters. As mentioned above, TAA/TE-SP can also be used in conjunction with sigmoidal rate expressions to reveal kinetic and thermodynamic information. In other applications (not shown) TAA/TE-SP could be used with logistic or inverted logistic-type functions to explore statistical artifacts tied to aging processes.

To demonstrate utility of the disclosed methods, several examples are given below in FIGS. 1 through 13 that examine various aspects of various embodiments disclosed herein. For the sake of brevity, each figure is listed with a short description.

The systems and methods of the present disclosure may, in some embodiments, provide and/or include the following features and/or advantages over other systems and/or methods:
The systems and methods of the present disclosure may describe the aging consequences of periodic interactions between one or more Transient Active Agents (TAA) and Transient Events (TE) with one or more Static or Semi-static Populations (SP).
Describing the aging consequences may include producing predictive outcomes (which may include, e.g., an aging profile). The predictive outcomes may depend on chosen model parameters, which may be tied to the system materials, system design and operating conditions. This enables optimization of both materials and the system usage.
The systems and methods of the present disclosure may provide for both diagnostic and predictive of aging mechanisms.
In one example, the systems and methods of the present disclosure may be applied to batteries. In this example application, solvents (TAA) that react with electrode surface sites (SP) from early-life formation processes to long-term aging can be modeled.
Hundreds and thousands of TAA and TE cycles can be investigated, within practical limits of system longevity.
In some embodiments, the systems and methods of the present disclosure may include an approach that is does not rely on assumptions about kinetic reaction rate constants or reaction orders, but such terms can be derived from model results. This method can be used in concert with existing physics-based components (e.g., CellSage components) and can support machine learning (ML).
In some embodiments the systems and methods of the present disclosure may allow for analysis of two TAA modes (a TAA cycle occurs when TAA-to-SP interactions exist under reactive conditions). In a first mode, TAA has a fixed initial concentration that is not refreshed over time. In a second mode, a small amount of TAA is introduced with each TAA cycle.
Example Variables herein: Initial TAA:SP molar ratio, temperature, SP particle fracturing and battery cell polarization.
Some systems and methods of the present disclosure support statistical predictions on population dynamics and longevity and may be valuable to data analytics and machine learning (DA&ML) by providing a physical or physics-based framework to guide and properly bound DA&ML.
Some systems and methods of the present disclosure could inform real-time management systems to facilitate system controls that will increase the life or performance of the system and allow avoidance of unsafe operating conditions.

Some systems and methods of the present disclosure may be generalized, allowing for a high number of applications that involve discrete transient inputs: aging trends of common battery data elements, aging consequences under arbitrary, customized system operation, catalyst and reactant/product outcomes, influences of TAA and TE on SP for natural systems (geological, biological, etc.), influences of TAA and TE on SP for man-made systems and materials, population dynamics.

Some of the improvements that may be provided by some systems and methods of the present disclosure include longer-lived batteries, safer batteries, increased proliferation of battery energy storage, and increased consumer confidence thereof. Additional improvements include providing additional information regarding cause-and-effect on system aging and increased ease in using a modeling framework to support optimization of design and use conditions.

### Example of Other Application: Platinum (Pt) Oxidation Model

The following mathematical development may be used for predicting TAA/TE-SP behavior of platinum oxidation in a microreactor at various temperatures. In this use case the Mode 2 modeling basis is used wherein small pulses of an Argon-Oxygen gas mixture (oxygen is TAA) are periodically pulsed into a small reactor housing a thin zone of platinum particles (activated Pt sites represent SP). Over successive pulses the platinum metal is converted to platinum oxide. The fraction of active Pt sites available at a given T over successive j pulses is given as

$${θ}_{j} \left(T\right) = \frac{{N}_{s i t e s} \left(T\right) - {β}_{j - 1} \left(T\right)}{{N}_{s i t e s} \left(T\right) + {α}_{j} \left(T\right)} ,$$

where

$${α}_{j} \left(T\right) = {\sum }_{k = 1}^{n} {\dot{N}}_{c o l l .}^{G {S}^{′}} \left(k , T\right) Δ {t}_{k}$$

for a single j pulse, and

$${β}_{j - 1} \left(T\right) = {\sum }_{j = 1}^{j - 1} \left[{θ}_{j} \left(T\right) {\sum }_{k = 1}^{n} {\dot{N}}_{c o l l .}^{G {S}^{′}} \left(k , T\right) Δ {t}_{k}\right]$$

Note that for αⱼ(T) and βⱼ₋₁(T) the k-to-n summand covers each entire pulse time through the micro reactor, e.g., two seconds.

An effective number of convertible Pt sites at a given temperature may be given as:

$${N}_{s i t e s} \left(T\right) = {N}_{s i t e s}^{o} exp \left(- \frac{{E}_{a , s t i c k} \left(1 + \frac{1}{e}\right)}{R} \left(\frac{1}{T} - \frac{1}{{T}_{r e f , s i t e s}}\right)\right) ,$$

where

$${N}_{s i t e s}^{o} \text{is}$$

the maximum number of active available Pt^{o} sites at a reference temperature, given the mass and specific total surface area of platinum metal.

A total gas-surface collision rate (total interaction rate) in reaction zone at time step k may be given as:

$${\dot{N}}_{c o l l .}^{G S , t o t} \left(k , T\right) = {N}_{p a r t i c l e s}^{R X N} {A}_{p a r t i c l e} ϕ {C}_{{O}_{2} , k} {N}_{A v} {\left(\frac{1000 R T}{2 π {M}_{{O}_{2}}}\right)}^{\frac{1}{2}} .$$

A total effective collision rate (effective interaction rate) that results in conversion of Pt^{o} sites to PtO may be given as:

$${\dot{N}}_{c o l l .}^{G {S}^{′}} \left(k , T\right) = {\dot{N}}_{c o l l .}^{G S , t o t} \left(k , T\right) {v}_{{O}_{2}} {f}_{s t i c k} \left(T\right) {\left[{\text{v}}_{{O}_{2}} \left(k , T\right) \frac{\text{Δ} {\text{t}}_{k}}{\text{Δ} \text{x}}\right]}^{\frac{1}{2}} ,$$

for

$${f}_{s t i c k} \left(T\right) = e x p \left(- \frac{{E}_{a , s t i c k}}{R T}\right) .$$

A total number of collisions that result in Pt oxidation over Δtₖ may be given as:

$${\dot{N}}_{c o l l .}^{G {S}^{′}} \left(k , T\right) = {\dot{N}}_{c o l l .}^{G {S}^{′}} \left(k , T\right) Δ {t}_{k} .$$

The fraction of unused oxygen (breakthrough) is given by the following statistical expression involving the available active Pt^{o} sites:

$${\text{X}}_{{O}_{2 , \text{unused}}} \left(j , T\right) = M \left(T\right) \left[1 - {\left(1 + {\left(\frac{1 - {θ}_{j} \left(T\right)}{{θ}_{j} \left(T\right)}\right)}^{φ}\right)}^{- 1}\right] ,$$

where

$$φ = 2 + \left(1 - e x p \left(1 - \frac{1}{{θ}_{j}^{2} \left(T\right)}\right)\right) ,$$

which allows the order φ to vary between 2 (surface-dominated processes) and 3 (O₂ migration to Pt sites involves more 3D transport). Surface or two-dimensional processes will prevail at early pulses where plentiful “easy” Pt sites are accessed by oxygen, whereas more complex oxygen transport is required to connect oxygen with remaining active sites (possibly less accessible due to poor placement) that could require more tortuous 3-dimensional migration. M(T) varies between zero and unity and accounts for the effects of oxygen desorption from Pt that can happen at higher temperatures:

$$M \left(T\right) = 1 - δ \left(T\right)$$

$$δ \left(T\right) = {δ}_{r e f} exp \left(- \frac{{E}_{a , t h e r m .}}{R} \left(\frac{1}{T} - \frac{1}{{T}_{r e f}}\right)\right)$$

For some embodiments disclosed herein:

$${E}_{a , t h e r m .} = 39.5 \text{kJ} / \text{mole,} \text{and}$$

$${E}_{a , s t i c k} = \text{35} \text{kJ} / \text{mole} \text{.}$$

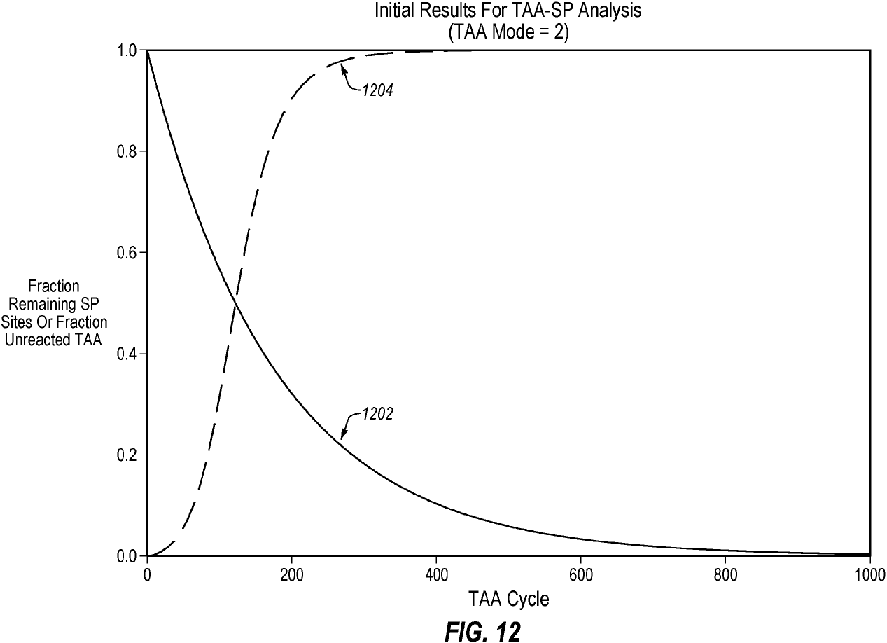

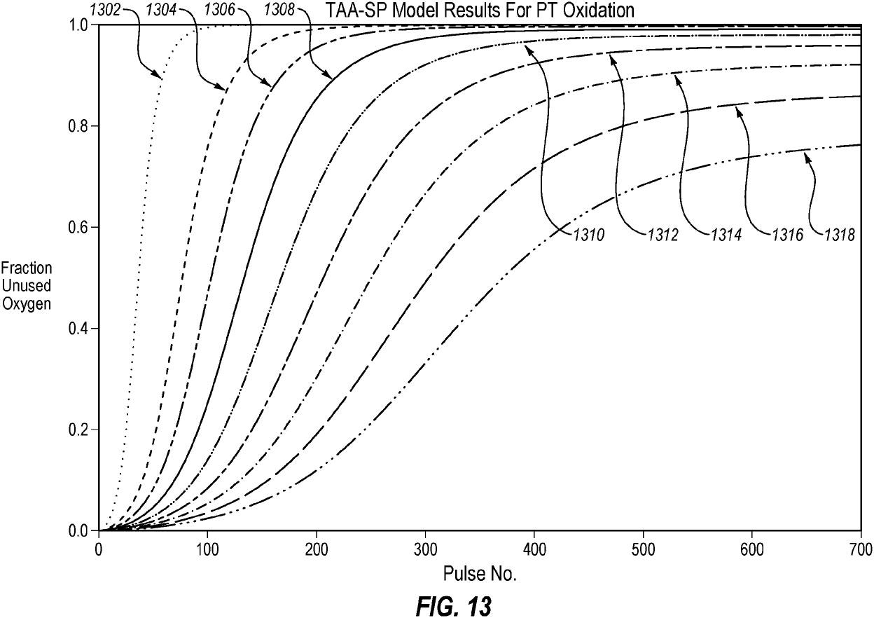

The applicable TAA Mode 2 approach and results from applying the model over a wide range of temperature, are illustrated in FIGS. 12 and 13 respectively. Unused oxygen appears at earlier pulse numbers for lower temperatures due to fewer responsive Pt sites at these temperatures, a consequence of lower collision energies between the oxygen gas and the Pt solid phase.

Turning now to the drawings, FIGS. 1A, 1B, and 1C illustrates examples of common battery test data elements that could be used as aging metrics according to one or more embodiments. Data elements from typical electrochemical cell charging protocols involve conditions of constant current (CC), constant voltage (CV) and rest. FIG. 1A illustrates a profile 102 for current during charge, FIG. 1B illustrates a profile 104 for voltage during charge, and FIG. 1C illustrates a profile 106 for voltage during rest. Of particular interest are (Δtcc, ΔCcc ) — the charging time to reach the maximum voltage and the change in capacity associated therewith, (Δtcv, ΔCcv ) — the time between when the cell is charged to the maximum voltage and when the charging current reaches a minimum and the change in capacity associated therewith, Δtcc / Δtcv - the ratio between the charging time to reach the maximum voltage and the time between when the cell is charged to the maximum voltage and when the charging current reaches a minimum, ΔCcc / ΔCcv the ratio between the capacity associated with charging time to reach the maximum voltage and the capacity associated with the time between when the cell is charged to the maximum voltage and when the charging current reaches a minimum, Atᵣₑₛₜ - a time associated with the battery resting after charging and ΔVᵣₑₛₜ - a voltage difference associated with the battery resting after charging, which are metrics that will reflect aspects of cell aging trends. Note that ΔCcc = I_{ch} *Δtcc.

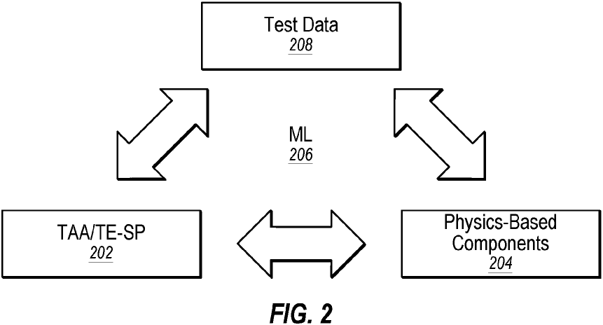

FIG. 2 illustrates a combination of computational methods according to one or more embodiments. Specifically, FIG. 2 illustrates a combination of computational methods (including physics, kinetic, and thermodynamic bases for aging processes including TAA/TE-SP 202 and physics-based components 204 (e.g., CellSage components), which may be used along with machine learning (ML 206) on the nature of aging trend dependencies in Test Data 208. This may be described as physics-guided machine learning (PGML). One advantage of the combination may be that it may allow a robust platform to support machine learning (ML).

For example, TAA/TE-SP 202 may include physics-based models. Physics-based components 204 may be used with TAA/TE-SP 202 to assess the cause-and-effect relationships between system stress factors and system aging. TAA/TE-SP 202 may provide explicit consideration of the chief factors tied to periodic transient events that impact battery stability and life in terms of the battery materials, battery design and arbitrary operating conditions. Using TAA/TE-SP 202 may provide increased knowledge of cause-and-effect on system aging and how the modeling framework can support optimization of design and use conditions. Additionally, TAA/TE-SP 202 can be used as an independent yet complementary route to existing physics-based components 204 to diagnose and predict aging processes in battery and non-battery applications. Additionally, MI, 206 techniques can be employed to provide additional knowledge and/or ability to use TAA/TE-SP 202 in designing and/or diagnosing batteries.

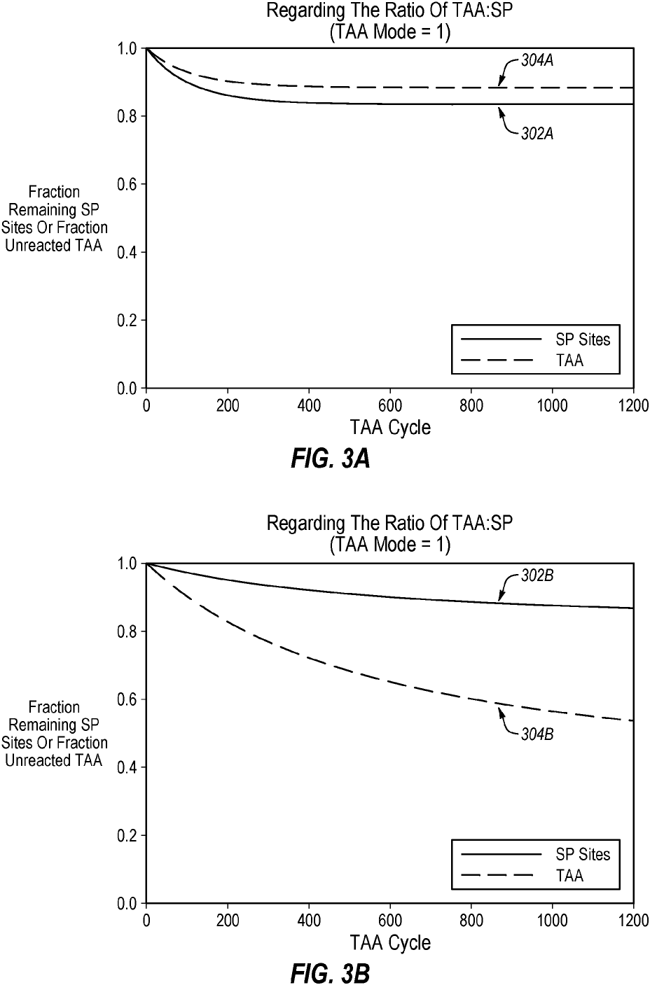

FIGS. 3A and 3B illustrate examples of TAA-SP model predictions at 30° C. for remaining fraction of SP sites and unreacted TAA for TAA:SP = 10:7 (illustrated in FIG. 3A), and TAA:SP = 2:7, (TAA mode 1) (illustrated in FIG. 3B), according to one or more embodiments. In particular, FIG. 3A illustrates a data plot 302A representing a fraction of remaining SP sites and a data plot 304A representing a fraction of unreacted TAA for TAA:SP = 10:7. And, FIG. 3B illustrates a data plot 302B representing a fraction of remaining SP sites and a data plot 304B representing a fraction of unreacted TAA for TAA:SP = 2:7. FIGS. 3A and 3B include graphs illustrating examples of aging profiles, e.g., that may be obtained using some embodiments.

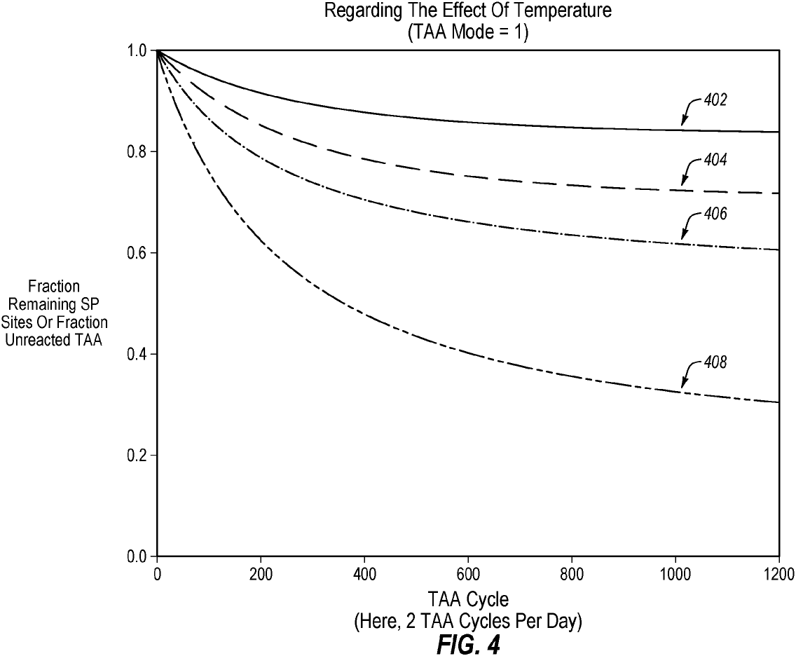

FIG. 4 illustrates examples of TAA-SP model predictions at 30 and 50° C. for remaining fraction of SP sites and unreacted TAA for TAA:SP = 4:7, (TAA mode 1), with no SP particle fracturing, according to one or more embodiments. In particular, FIG. 4 illustrates: a data plot 402 representing fraction of remaining SP sites at 30° C., a data plot 404 representing a fraction of unreacted TAA at 30° C., a data plot 406 representing a fraction of remaining SP sites at 50° C., and a data plot 408 representing a fraction of unreacted TAA at 50° C. FIG. 4 includes a graph illustrating examples of aging profiles, e.g., that may be obtained using some embodiments.

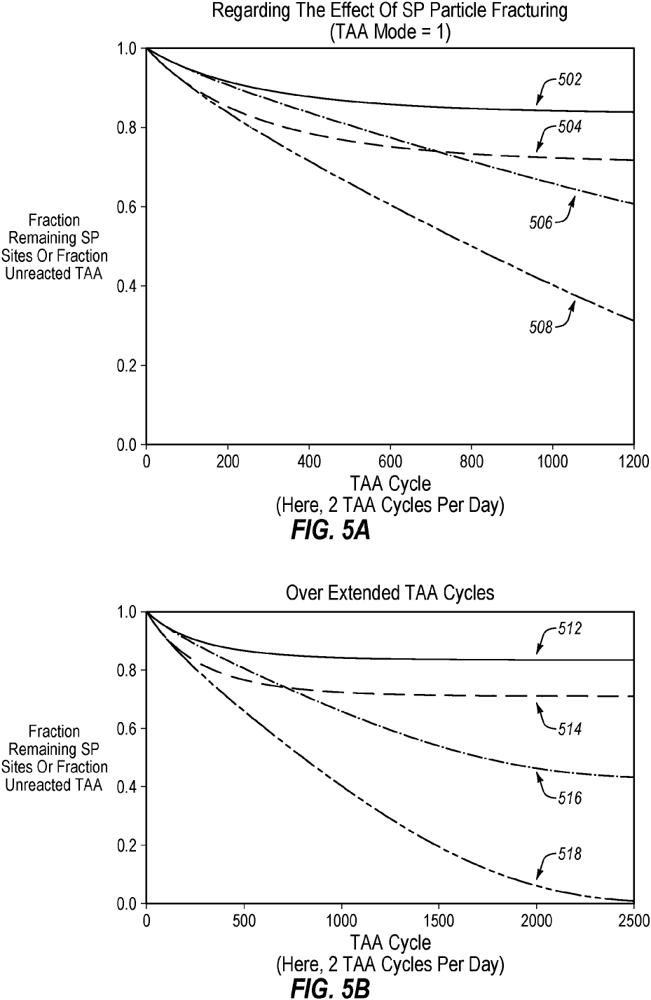

FIGS. 5A and 5B illustrate examples of TAA-SP model predictions at 30° C. for remaining fraction of SP sites and unreacted TAA for TAA:SP = 4:7, with SP particle fracturing at show conditions (TAA mode 1) according to one or more embodiments. In particular, FIG. 5A illustrates a data plot 502 representing a fraction of remaining SP sites without fracturing, a data plot 504 representing a fraction of unreacted TAA without fracturing, a data plot 506 representing a fraction of remaining SP sites with fracturing, and a data plot 508 representing a fraction of unreacted TAA with fracturing. In TAA Mode 1, (illustrated in FIG. 5A) the TAA population is solely based on an initial amount, that is, TAA is not refreshed or reintroduced. In battery scenarios, the results could be compared to electro-catalysis, where electrons in/on SP facilitate the interactions between SP and dwindling TAA. The conditions of fracturing are that electrode particles undergo an average of 10% reduction in diameter every 100 TAA cycles due to events that cause particle fracturing.

FIG. 5B illustrates over extended TAA cycles. In case A, which includes a data plot 512 representing a fraction of remaining SP sites and a data plot 514 representing a fraction of unreacted TAA, limits are being reached due to the activation energy (Ea) tied to SP site availability. In case B, which includes a data plot 516 representing a fraction of remaining SP sites and a data plot 518 representing a fraction of unreacted TAA, limits are being reached due to high TAA consumption that leads to low TAA availability. FIGS. 5A and 5B include graphs illustrating examples of aging profiles, e.g., that may be obtained using some embodiments.

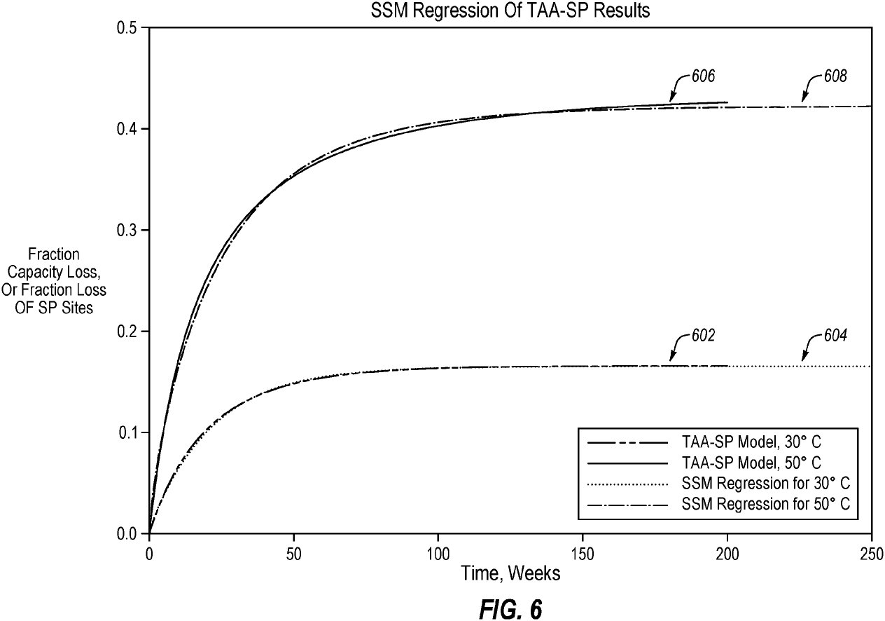

FIG. 6 illustrates results for single-sigmoid model (SSM) regression of TAA-SP model predictions at 30 and 50° C. (as from FIG. 4) for fractional loss (deactivation) of SP sites where TAA:SP = 4:7 according to one or more embodiments. In particular, FIG. 6 illustrates a data plot 602 representing a fraction of remaining SP sites for a TAA-SP model at 30° C., a data plot 604 representing a fraction of remaining SP sites for an SSM-regression model of at 30° C., a data plot 606 representing a fraction of remaining SP sites for a TAA-SP model at 50° C., and a data plot 608 representing fraction of remaining SP sites for an SSM-regression model of at 50° C. Note that in FIG. 6, the cycle basis has been converted to a time basis. FIG. 6 includes a graph illustrating examples of aging profiles, e.g., that may be obtained using some embodiments.

Referring to FIG. 6, the results illustrated mimic capacity loss curves that are based on loss of lithium inventory (LLI). Single-sigmoid model (SSM, e.g., used in the equation f = 2 * m * (0.5 - 1/(1 + exp((a * x)^b)))) regression parameters are similar to those found for LLI cases. This demonstrates how kinetic information can be extracted from TAA-SP results.

For the 50° C. TAA-SP model, the parameters are according to the following table

| Parameter | Value | StdErr | CV(%) | Dependencies |
|---|---|---|---|---|
| m | 4.226e-1 | 6.542e-4 | 1.548e-1 | 0.6421994 |
| a | 7.448e-2 | 5.564e-4 | 7.470e-1 | 0.5464488 |
| b | 6.827e-1 | 4.793e-3 | 7.022e-1 | 0.6548519 |

further, R² = 0.9985.

For the 30° C. TAA-SP model, the parameters are according to the following table

| Parameter | Value | StdErr | CV(%) | Dependencies |
|---|---|---|---|---|
| m | 1.653e-1 | 8.933e-5 | 5.404e-2 | 0.4168143 |
| a | 7.830e-2 | 2.480e-4 | 3.168e-1 | 0.4578852 |
| b | 7.949e-1 | 2.602e-3 | 3.274e-1 | 0.5166623 |

further, R² = 0.9997.

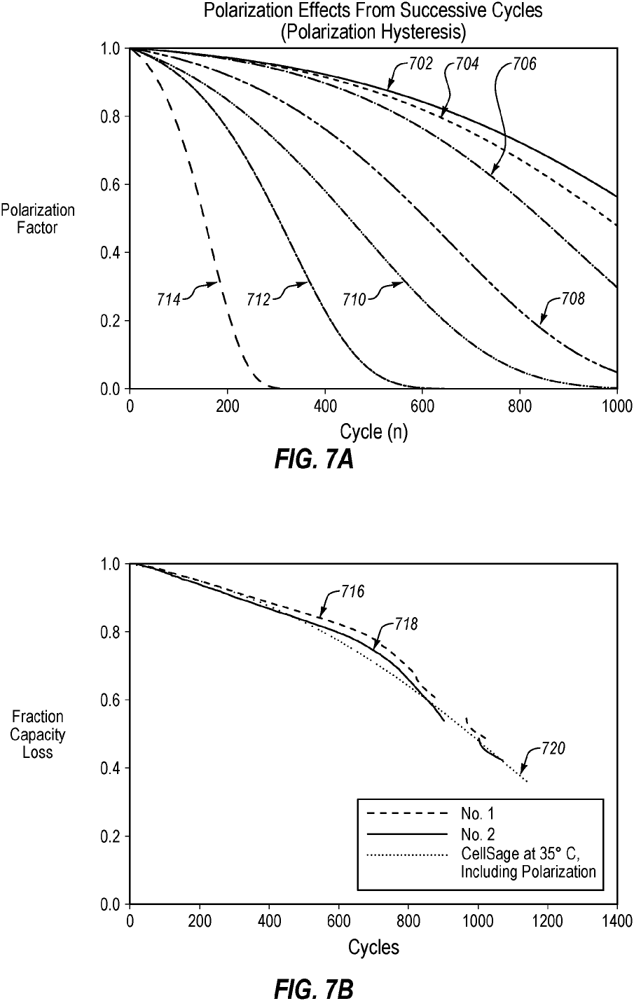

FIGS. 7A and 7B illustrate results for prediction of polarization effects through the polarization factor, considering various model parameters (see Eq. 19) according to one or more embodiments. Here, parameters a and b correspond to terms γₚₒₗ and Δγₚₒₗ in Eq. 19. The right-side plot illustrates application of Eq. 19 to real-world data for 4S1P lithium-ion battery packs. FIGS. 7A and 7B include graphs illustrating examples of aging profiles, e.g., that may be obtained using some embodiments.

Referring to FIGS. 7A and 7B collectively, the methods of this disclosure allow insights into polarization hysteresis that is carried forward through successive cycles, say, that have insufficient rest time in between. FIG. 7A illustrates the polarization factor over various input conditions. This factor describes what additional capacity loss (typically reversible) would occur on top of normal irreversible aging where no polarization is assumed. Parameters a and b may be functions of materials, rate, T, SOC range under cycling etc. FIG. 7B illustrates application to a lab dataset for a 4S1P pack scenario. This method fits directly into the TAA-SP approach since the process of polarization hysteresis is driven by distinct, yet connected cycling events. While FIGS. 7A and 7B collectively illustrate application to capacity, application to impedance (reversible conductance loss) can also be surmised.

FIG. 7A illustrates data plots representing a polarization factor as a function of cycles, in particular: y = Mₚₒₗ * ((1 - a * (1 + b) ^n) ^n) where Mₚₒₗ = 1 and: for data plot 702, a = 0.0001 and b = 0.00175; for data plot 704, a = 0.0001 and b = 0.002; for data plot 706, a = 0.0001 and b = 0.0025; for data plot 708, a = 0.00025 and b = 0.0025; for data plot 710, a = 0.0005 and b = 0.0025; for data plot 712, a = 0.0005 and b = 0.005; and for data plot 714, a = 0.001 and b = 0.01.

FIG. 7B illustrates capacity loss behavior for the two test packs and suggests that cell polarization is playing an increasing role over time to diminish capacity. CellSage results give reasonable trends when a polarization function is included with the core aging mechanisms at 35° C. In particular, FIG. 7B illustrates a data plot 716 representing fractional capacity loss of Pack No. 1 and a data plot 718 representing a fractional capacity loss of Pack No 2. FIG. 7B also illustrates a data plot 720 representing a fractional capacity loss of a CellSage model at 35° C. including polarization.

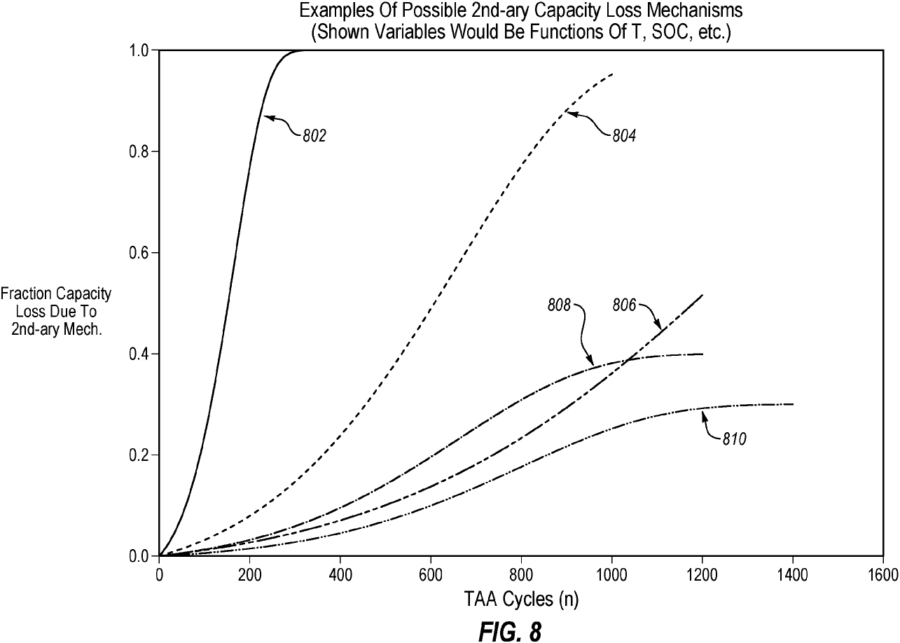

FIG. 8 illustrates results for prediction of secondary aging effects, considering various model parameters (see Eq. 20) according to one or more embodiments. Here, parameters c and d correspond to terms λ,_{3D} and Δλ_{3D} in Eq. 20.

Referring to FIG. 8, the M_{3D} term represents the thermodynamic or mechanical limit to the secondary mechanism at the conditions of interest. It, like (c,d), will be a function of temperature, among other factors. M_{3D} can be surmised from typical CellSage sigmoidal rate analyses.

FIG. 8 illustrates a fractional capacity loss due to secondary mechanisms, in particular: y = M_{3D} * (1 - (1 - c * (1 + d) ^n) ^n) where: for a data plot 802, c = 0.001, d =0.01, and M_{3D} = 1.0; for a data plot 804, c = 0.00025, d =0.0025, and M_{3D} = 1.0; for a data plot 806, c = 0.0001, d =0.0015, and M_{3D} = 1.0; for a data plot 808, c = 0.00025, d =0.0025, and M_{3D} = 0.4;and for a data plot 810, c = 0.00015, d =0.0025, and M_{3D} = 0.3.

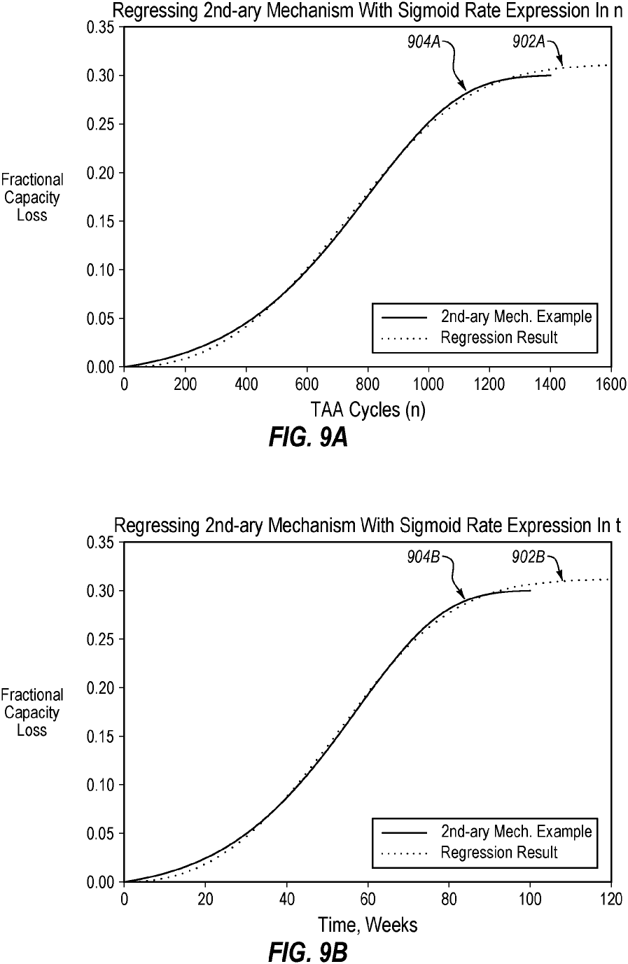

FIGS. 9A and 9B illustrate results for single-sigmoid model (SSM) regression of capacity loss and TAA-SP model predictions of capacity loss for an example secondary aging mechanism according to one or more embodiments. In particular, FIG. 9A illustrates a data plot 902A representing a regression result of a fraction of capacity loss and a data plot 904A representing a fraction of capacity loss for an example secondary aging mechanism. FIG. 9B illustrates a data plot 902B representing a regression result of a fraction of capacity loss and a data plot 904B representing a fraction of capacity loss for an example secondary aging mechanism. FIG. 9A illustrates results with a cycle basis and FIG. 9B illustrates results for a time basis. Overall results indicate a second-order aging process for this mechanism, which is commonly observed in real battery test data at extended time or cycle numbers.

Referring to FIGS. 9A and 9B collectively, the results mimic capacity loss curves that are based on loss of active host material (LAM). Single-sigmoid model regression parameters (a, b, m) are similar to those found for LAM cases. This demonstrates how kinetic information can be extracted from TAA-SP results.

FIG. 9A illustrates the sigmoidal rate expression in terms of n as y = 2 * m * (0.5 - 1 / (1 + exp((a * n) ^b)) where m = 0.3118; a = 0.0014; b = 2.2847; and R² = 0.999. FIG. 9B illustrates the sigmoidal rate expression in terms of time as y = 2 * m * (0.5 - 1 / (1 + exp((a * t) ^b)) where m = 0.3118; a = 0.0197; b = 2.2847; and R² = 0.999. FIGS. 9A and 9B include graphs illustrating examples of aging profiles, e.g., that may be obtained using some embodiments.

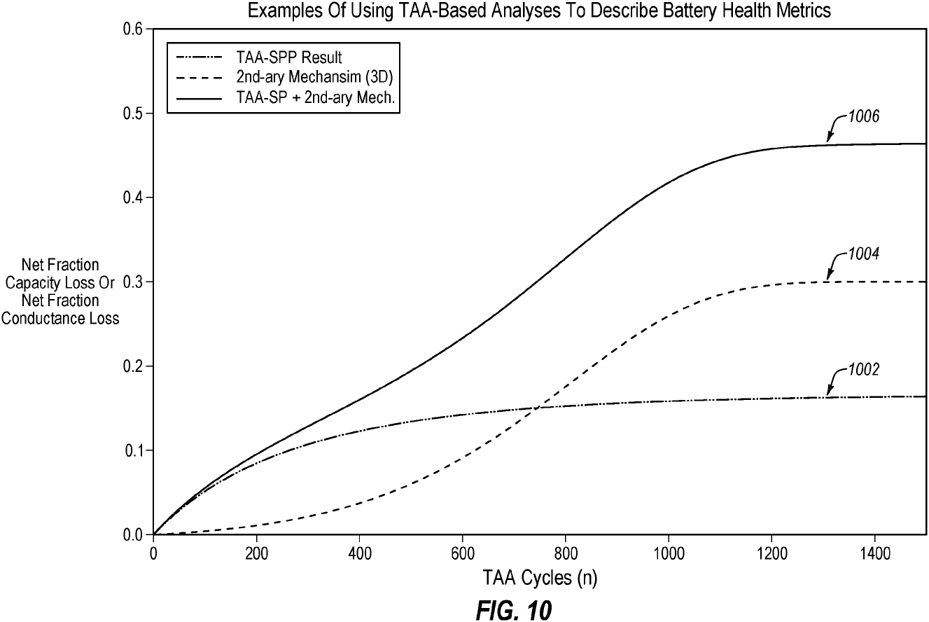

FIG. 10 illustrates results for using TAA-SP model predictions at 30° C. to describe a two-mechanism aging process for lithium-ion batteries involving loss of lithium inventory (LLI) and loss of active host materials (LAM) according to one or more embodiments. Here, initial TAA:SP = 4:7. In particular, FIG. 10 illustrates a data plot 1002 representing a TAA-SPP result of LLI. FIG. 10 also illustrates a data plot 1004 representing LAM is a secondary mechanism (3D) result illustrated as M_{3D} * (1 - (1 - c * (1 + d) ^n) ^n) for the c = 0.0001, d = 0.003. FIG. 10 also illustrates a data plot 1006 representing the sum of LLI and LAM. The general shapes of the curves will depend on chosen model parameters, which are tied to the cell materials, cell design and operating conditions. Shown curves are similar to those found in aging data. FIG. 10 includes a graph illustrating examples of aging profiles, e.g., that may be obtained using some embodiments.

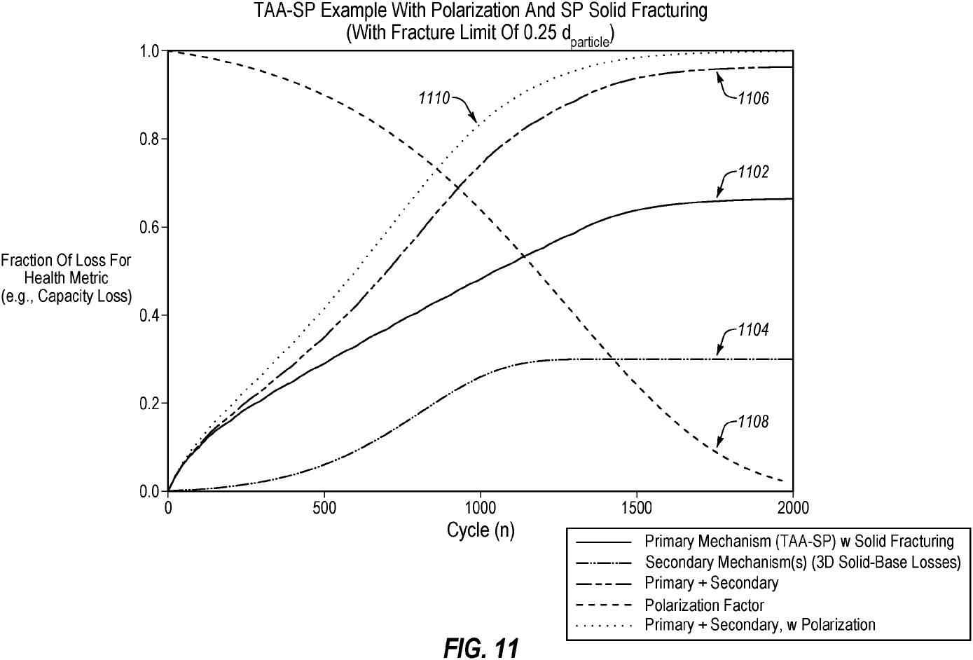

FIG. 11 illustrates results for using TAA-SP model predictions at 30° C. to describe a three-mechanism aging process for lithium-ion batteries involving primary aging (LLI), secondary aging (LAM), polarization and SP particle fracturing according to one or more embodiments. Here, initial TAA:SP = 4:7. In particular, FIG. 11 illustrates capacity loss 1102 resulting from a primary mechanism with solid fracturing as determined by a TAA-SP approach, capacity loss 1104 resulting from a secondary mechanism or mechanisms (e.g., 3D solid-based losses), capacity loss 1106, which is the sum of 1102 and 1104, polarization factor 1108, and capacity loss 1110, which is the sum of 1102, 1104, and 1108. The general shapes of the curves will depend on chosen model parameters, which are tied to the cell materials, cell design and operating conditions. FIG. 11 includes a graph illustrating examples of aging profiles, e.g., that may be obtained using some embodiments.

Some of the assumptions used in the modeling illustrated in FIG. 11 include:

Terms for TAA-SP Interactions:
Temperature = 30.0000000° C.
Interaction (Reaction) Zone: 1 cm by 1 cm by SP depth of 4.99999989E-03 cm
Representative average diameter of SP particle =10.0000000 micron
SP particle sphericity factor (1 = perfect sphere): 1.13999999
Surface Area in Reaction Zone = 22.2300014 cm2
Void fraction within SP = 0.349999994
Initial total molar concentration of SP sites in electrodes (ave.) = 7.00000000 M
Initial total molar concentration of target TAA (i) in void volume = 10.0000000 M
Initial Active Available SP sites in Reaction Zone = 2.26989887E+18
Initial Available TAA (species i) in Reaction Zone = 1.05385793E+19
Ratio of Initial Active Available SP sites to Target TAA = 0.215389460
Activation Energy for TAA-SP interactions =42.0000000 kJ/mole
Activation Energy for SP site activation/availability =30.0000000 kJ/mole
Maximum Fraction of Deactivated SP sites possible at this T = 0.165684193
1 - (Resiliency factor) = 1.11490897E-08
Number of TAA cycles per day = 2
Number of TAA cycles between particle fracture events = 100
Average fraction reduction of SP particle diameters due to each particle fracturing event = 0.100000001

Terms for Polarization Effects and Secondary Loss Mechanisms:
Theoretical maximum extent of reversible performance loss due to polarization = 1.00000000
Polarization increment (reference) = 9.99999975E-05
Polarization increment (growth) = 1.50000001E-03
Theoretical maximum extent of aging due to secondary mechanism(s) (3D) = 0.300000012
Secondary mechanism increment (reference) = 9.99999975E-05
Secondary mechanism increment (growth) = 3.00000003E-03

FIG. 12 illustrates example results for TAA-SP model predictions under Mode 2, where a small amount of TAA is introduced with each TAA cycle according to one or more embodiments. In particular, FIG. 12 illustrates a data plot 1202 representing a fraction of remaining SP sites and a data plot 1204 representing a fraction of unreacted TAA. FIG. 12 includes a graph illustrating examples of aging profiles, e.g., that may be obtained using some embodiments.

Referring to FIG. 12, the TAA breakthrough curve coincides with diminished availability of unreacted or unconverted SP sites. TAA will appear different than shown if it has a finite initial amount that is not renewed with each TAA cycle (mode 1). In that case, the only “reactant” that is renewed is electrons.

FIG. 13 illustrates results for TAA-SP model predictions under Mode 2 for the case of platinum oxidation at various temperatures according to one or more embodiments. Shown are the oxygen (TAA) breakthrough curves. In particular, FIG. 13 illustrates a data plot 1302 representing a fraction of unused oxygen per pulse at 0° C., a data plot 1304 representing a fraction of unused oxygen per pulse at 50° C., a data plot 1306 representing a fraction of unused oxygen per pulse at 75° C., a data plot 1308 representing a fraction of unused oxygen per pulse at 100° C., a data plot 1310 representing a fraction of unused oxygen per pulse at 125° C., a data plot 1312 representing a fraction of unused oxygen per pulse at 150° C., a data plot 1314 representing a fraction of unused oxygen per pulse at 175° C., a data plot 1316 representing a fraction of unused oxygen per pulse at 200° C., and a data plot 1318 representing a fraction of unused oxygen per pulse at 225° C. The model considers a micro-reactor scenario (e.g., a 4 ×38 mm reactor) that has a thin Pt reaction zone mid-reactor, and the reactor receives short periodic pulses (e.g., 2.55e14 molecules) of mixed gas containing argon and oxygen at a 4:1 mole ratio. The results shown in FIG. 13 illustrate evidence of thermal desorption of oxygen.

Some embodiments of the present disclosure (including, e.g., the TAA/TE-SP (abbreviated as TAA/SP below) methodology) include analyses of transient events whose conditions and frequency are parameters within the modeling framework. This enables descriptions of kinetic reactive or interactive processes in complex dynamic systems. Here are discussed additional aspects of model features and conditions of use.

In the example case of batteries, cycling and calendar-life conditions determine the nature of interactions at the electrode surfaces with the electrolyte reactant species. Battery cycling conditions create an environment of electro-catalysis at the cathode and anode surfaces that may be captured by one or more of the methods described herein. As discussed earlier, cell design attributes regarding particle sizes, rheological terms, electrode and electrolyte loadings, etc. set the context for understanding the physical environment under which aging will proceed. Some methods of the present disclosure are independent of the sigmoidal rate expression (SRE) method, yet they may provide a link between the chosen cell materials and use conditions with the aging consequences. One outcome of this link is the determination of the maximum extent of reaction (or, degradation related to system aging) under the chosen system use conditions, which if known a priori would remove some uncertainties within machine learning analyses.

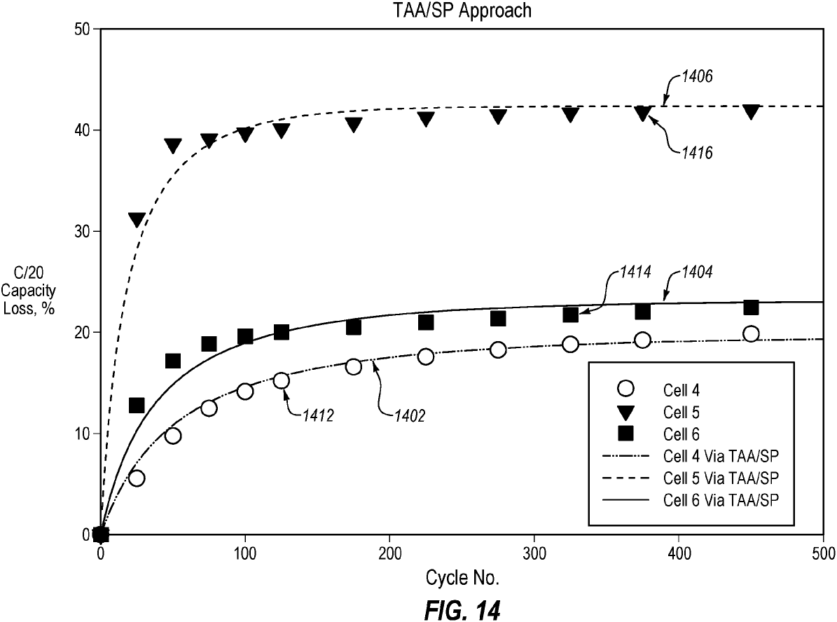

FIG. 14 shows the result of applying the TAA method on three Li-ion battery cells (denoted 4, 5, 6) that are comprised of a graphite anode, a 5-3-2 form of NiMnCo-oxide cathode, and an electrolyte containing ethylene carbonate, ethyl methyl carbonate and LiPF₆. These cells were tested under a cycling protocol including (A) a charging protocol based on a 10-minute charge for empty to full cell (this is termed a 6C charge rate), (B) discharging from full to empty cell over two hours, and (C) 15-minute rests in between. A complete “cycle” is the sequential combination of all three elements. TAA/SP is used to predict and diagnose the behavior for the loss of lithium inventory (LLI) of these cells in terms of capacity fade, using the C/20 cycling basis as the standard. The TAA/SP predictions for Cell 4 are illustrated as data plot 1402, the TAA/SP predictions for Cell 5 are illustrated as data plot 1404, and the TAA/SP predictions for Cell 6 are illustrated as data plot 1406. While the dry cells (without electrolyte) were produced in a reputable US laboratory and tested under identical conditions, significant differences in aging between them are observed. The measured capacity loss for cell 4 is illustrated as data plot 1412, the measured capacity loss for cell 5 is illustrated as data plot 1414, and the measured capacity loss for cell 6 is illustrated as data plot 1416. This is likely due to inconsistent electrolyte filling procedures that caused uneven electrode wetting, with probable consequences toward lithium metal deposition at the anode and particle cracking due to increased stress under these conditions. Thus, the effective wetted electrode surface is a parameter in the TAA/SP model.

As can be seen in FIG. 14, the outputs of the TAA/SP and the outputs of the testing substantially correspond. The correspondence validates the TAA/SP approach, especially considering TAA/SP is a completely physical modeling framework. In the modeling process it was found that the effective wetting of cells 4, 5 and 6 were 99, 71 and 93%, respectively. Variations in wetting will cause disparities in available (usable) surface area. Lesser available electrode surface area will increase the effective local current density through the available area regions and raise the rate of TAA-SP interactions therein, raise impedance, cause polarization, and hence cause the rate of LLI loss to increase. The model also determined that there was early particle fracturing (more so for cells 5 and 6) that influenced the capacity loss rate at earlier cycles. Particle fracturing increases the electrode surface area on which reactive interactions with electrolyte can proceed and consume more of the available lithium ion inventory.

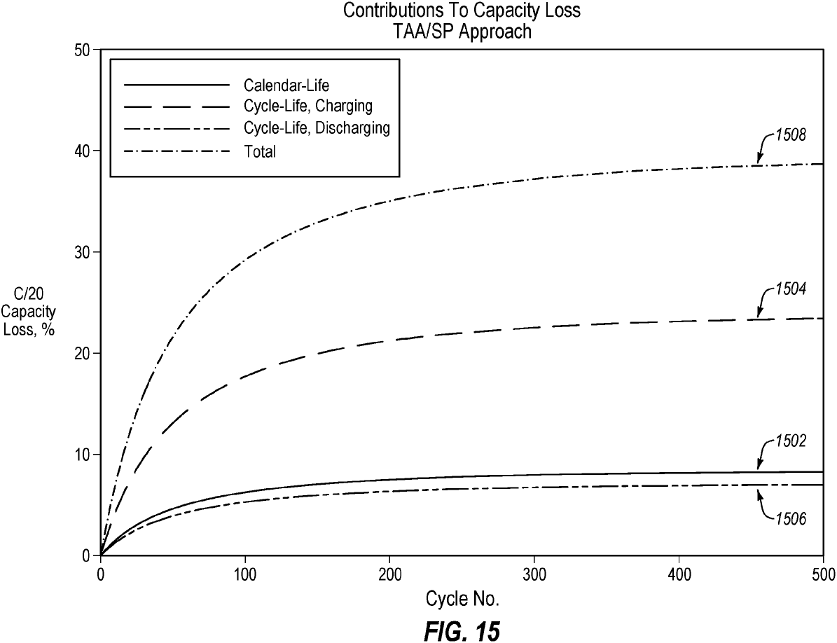

Another aspect of the TAA/SP approach is the determination of aging per the various cycling components (charging, discharging and rest). FIG. 15 shows a first approximation of this cycle component-wise analysis for Cell 4. The charging element provides a significant contribution to the cell aging, followed by the calendar-life contribution, then that from discharge conditions. In particular, FIG. 15 illustrates a data plot 1502 representing calendar life, a data plot 1504 representing cycle-file, charging, a data plot 1506 representing cycle-life, discharging, and an aggregate data plot 1508 representing the sum of data plot 1502, data plot 1504, and data plot 1506. The analysis behind FIG. 15 provides a physical basis to optimize the cell chemistry with cell use, to balance performance with cell life. The results illustrated in FIG. 15 was based on a simulation at 30° C. with 9 cycles / day (6 C charge, 0.5 C discharge) 19% of time at Cal-life.

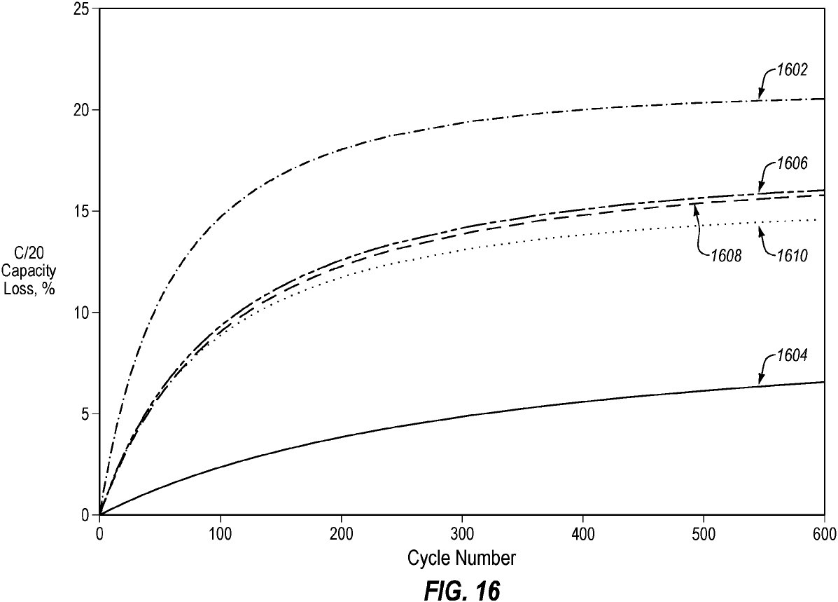

Aspects of how cycling conditions produce aging consequences are also seen in FIG. 16, where capacity loss resulting from various cycling conditions is illustrated. In particular, FIG. 16 illustrates a data plot 1602 representing a charging conditions 6 C CCCV, a data plot 1604 representing a charging conditions 4 C CCCV, a data plot 1606 representing charging conditions MS5-1, a data plot 1608 representing charging conditions MS5-2, and a data plot 1610 representing charging conditions MS12-1. In the parlance of battery terminology, 6 C CCCV indicates a 6 C-based charge starting at a constant current (CC), then transitioning to a constant voltage (CV) once an upper voltage limit has been reached. MS5-1,2 refer to five-step charge protocols, where the CC values start out large then progressively decrease over the charge time. MS12-1 is a 12-step charging protocol. The results illustrated in FIG. 16 were based on a simulation at 30° C. with 99% wetting and LLI as the primary aging mechanism.

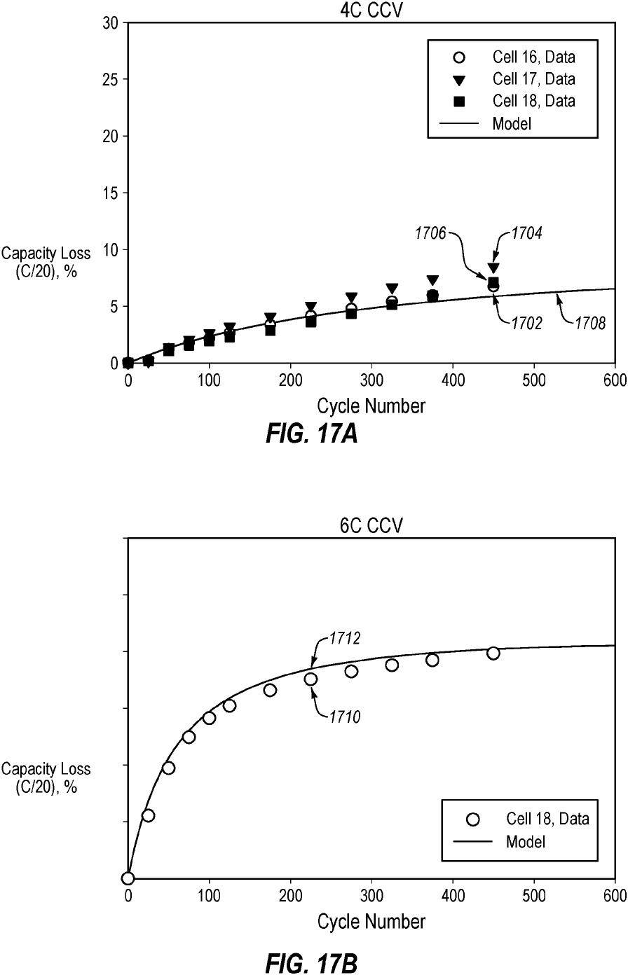

FIGS. 17A and 17B illustrate a comparison between TAA/SP predictions and lab data for the 4C CCCV (as illustrated in FIG. 17A) and 6C CCCV (as illustrated in FIG. 17B) conditions. These two test conditions render significantly different cell aging consequences. The model has a high fidelity, indicating adequate sensitivity to capture aging progression under these conditions. The model can also consider mixed-mode cycling conditions, for example, where cycling rates are allowed to vary between cycling events. FIG. 17A illustrates a data plot 1702 representing a capacity loss for a first cell (e.g., cell 16), a data plot 1704 representing a capacity loss for a second cell (e.g., cell 17), a data plot 1706 representing a capacity loss for a third cell (e.g., cell 18), a data plot 1708 representing modeled capacity fade data for the 4 C CCCV condition. FIG. 17B illustrates a data plot 1710 representing a capacity loss for a fourth cell (e.g., cell 4), a data plot 1712 representing modeled capacity fade data for the 6 C CCCV condition.

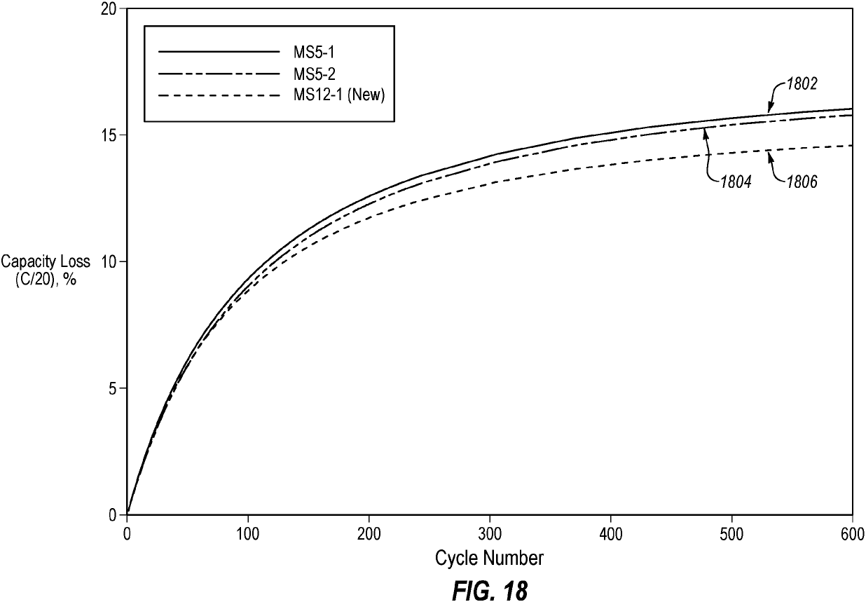

FIG. 18 shows a comparison of cell aging predicted by TAA/SP for three types of multi-step charge procedures. The TAA/SP approach can be used to survey multi-step charge protocols to minimize aging. In particular, FIG. 18 illustrates a data plot 1802 representing capacity loss related to MS5-1 charging conditions, a data plot 1804 representing capacity loss related to MS5-2 charging conditions, and a data plot 1806 representing capacity loss related to MS12-1 charging conditions. In this case the 12-step protocol provides a decrease of aging due to creating less stress within the cell as it transitions between steps.

FIG. 18 illustrates results of a comparison of TAA/SP analyses for various multi-step charge conditions. Multi-step charge protocols can be designed to decrease aging. Those shown in FIG. 18 are all 10-minute protocols that reach 80% SOC.

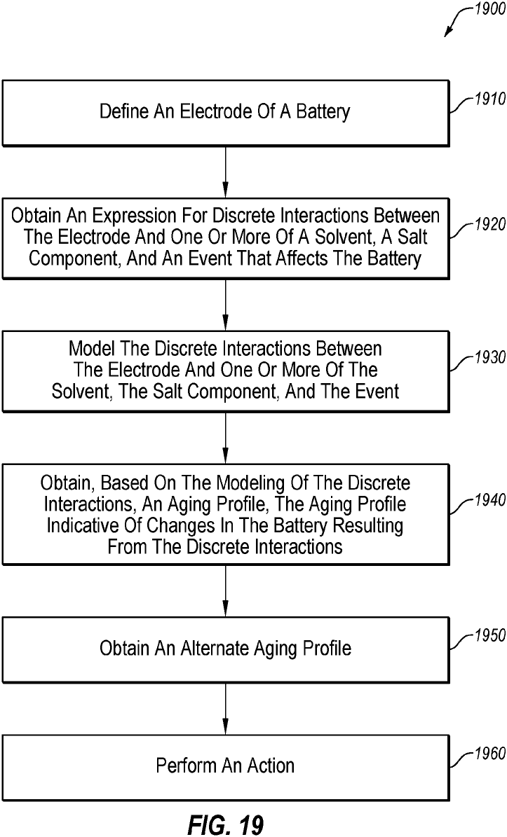

As a specific example of contemplated operations, FIG. 19 is a flowchart illustrating a method 1900 according to one or more embodiments. Method 1900 may be for analyzing changes in a battery that occur over time, the changes resulting from discrete interactions. According to method 1900 a battery system may be defined. For example, at block 1910, an electrode may be defined. Defining an electrode may include defining: molecular composition of the electrode, available surface sites (e.g., surface features that interact with TAA), surface sites accessible according to prevailing conditions (e.g., temperature and/or activation energy), molar concentration of sites, sensitivity toward TAA (reactivity), competing interactions between different TAA, and/or net sites deactivated over cumulative interactive cycles with TAA.

At block 1920, an expression for discrete interactions between the electrode and one or more of a solvent, a salt component, and an event that affects the battery may be obtained. The expression for discrete interactions may include sigmoid-based rate expressions (e.g., as described with reference to equation (16)), which reflect the net effective rate of one or more aging mechanisms.

At block 1930, discrete interactions between the electrode and one or more of the solvent, the salt component, and the event may be modeled.

At block 1940, an aging profile may be obtained based on the modeling of the discrete interactions. The aging profile may be indicative of changes in the battery resulting from the discrete interactions.

At block 1950, an alternative aging profile may be obtained. The alternative aging profile may be based on a battery that is defined differently than the battery. For example, an alternative battery may be defined including one or more of: an alternative electrode, an alternative solvent, and/or an alternative salt compound. Further, the alternative battery may be defined as undergoing one or more alternative events. Discrete interactions may be modeled relative to the alternative battery. Based on the modeling of the discrete interactions relative to the alternative battery, an alternative aging profile may be obtained.

At block 1960, an action may be performed. The action may be based on the alternative aging profile, or on a difference between the aging profile and the alternative aging profile. For example, if the alternative aging profile is preferable to the aging profile, the action may be taken to realize the alternative battery rather than the battery. Examples of actions include: redesigning the battery based on the alternative aging profile (and/or a comparison between the aging profile and the alternative aging profile), or designing another batter based on the alternative aging profile.

Additionally or alternatively, the aging profile and the alternative aging profile may be based on different conditions, e.g., different usage or charging conditions including such conditions as, temperatures, atmospheric pressures, or timings. For example, the discrete expression may include a factor that influences the discrete interactions. At block 1940, an aging profile may be obtained based on the discrete expression including a first factor. At block 1950, an alternative aging profile may be obtained based on the discrete expression including a second factor.

At block 1960, the actions performed may include comparing the aging profile and the alternative aging profile and recommending or implementing different conditions (e.g., usage or charging conditions) based on the aging profile and the alternative aging profile. For example, an aging profile may be based on a first factor (e.g., a first ambient temperature) and an alternative aging profile may be based on a second factor (e.g., a second ambient temperature). Based on the alternative aging profile being preferred over to the aging profile, a recommendation may be provided to a user that the battery be used and/or charged at the second ambient temperature rather than the first ambient temperature. Additionally or alternatively, based on the alternative aging profile being preferred over to the aging profile, a battery management system may be instructed relative to the use and/or charging of the battery.

In some embodiments, the action performed at block 1960 may include predicting a lifespan of a battery. The battery may be newly designed and/or created.

Additionally or alternatively, aging profile obtained at block 1940 may be based on first usage conditions and the alternative aging profile obtained at block 1950 may be based on second usage conditions. The first usage conditions may include conditions that a battery has undergone. The second usage conditions may include predicted usage conditions. In such cases, the alternative aging profile may be indicative of a remaining useful life of the battery under the second usage conditions (which may be the same as or different from the first usage conditions).

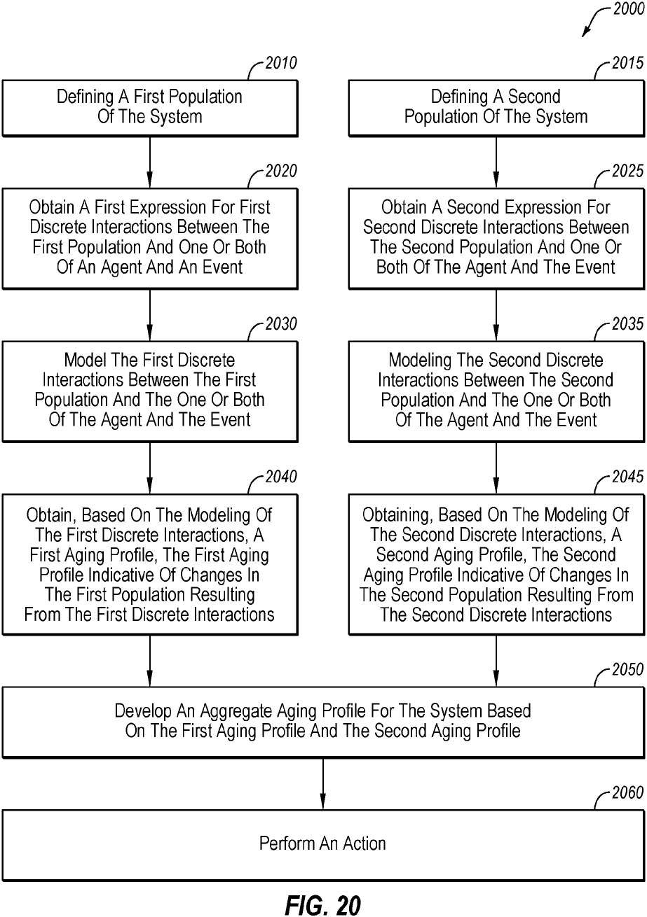

FIG. 20 is a flowchart illustrating another example method 2000 according to one or more embodiments.

At block 2010, a first population of a system may be defined. An electrode of a battery, or molecules within the electrode, may be an example of the first population of a system. Other populations (e.g., materials or organisms) and systems are within the scope of this disclosure.

At block 2020, a first expression for first discrete interactions between the first population and one or both of an agent and an event may be obtained. A solvent or a salt component may be an example of the agent. Other agents are within the scope of this disclosure.

At block 2030, the first discrete interactions between the first population and the one or both of the agent and the event may be modeled.

At block 2040, a first aging profile may be obtained based on the modeling of the first discrete interactions. The first aging profile may be indicative of changes in the first population resulting from the first discrete interactions.

At block 2015 a second population of the system may be defined. Another group of molecules of the electrode of the battery may be an example of the second population of the system. Other populations and systems are within the scope of this disclosure.

At block 2025 a second expression for second discrete interactions between the second population and the one or both of an agent and an event may be obtained.

At block 2035 the second discrete interactions between the second population and the one or both of the agent and the event may be modeled.

At block 2045 a second aging profile may be obtained based on the modeling of the second discrete interactions. The second aging profile may be indicative of changes in the second population resulting from the second discrete interactions.

At block 2050 an aggregate aging profile for the system may be developed based on the first aging profile and the second aging profile.

At block 2060, an action may be performed. The actions discussed above (e.g., with reference to block 1960 of FIG. 19) are examples of some of the actions that may be performed at block 2060. For example, designing another system based on the first aging profile, the second aging profile, and/or the aggregate aging profile may be the action performed at block 2060. As another example, determining to use or manage the system based on the first aging profile, the second aging profile, and/or the aggregate aging profile may be another example of the action performed at block 2060.

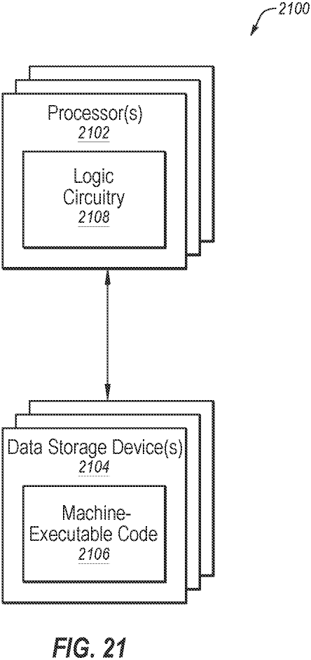

Modifications, additions, or omissions may be made to either or both of method 1900 and method 2000 without departing from the scope of the present disclosure. Furthermore, the outlined operations and actions are only provided as examples, and some of the operations and actions may be optional, combined into fewer operations and actions, or expanded into additional operations and actions without detracting from the essence of the disclosed embodiment. FIG. 21 is a block diagram of an example device 2100 that, in some embodiments, may be used to implement various functions, operations, acts, processes, and/or methods disclosed herein. The device 2100 includes one or more processors 2102 (sometimes referred to herein as “processors 2102”) operably coupled to one or more apparatuses such as data storage devices (sometimes referred to herein as “storage 2104”). The storage 2104 includes machine-executable code 2106 stored thereon (e.g., stored on a computer-readable memory) and the processors 2102 include logic circuitry 2108. The machine-executable code 2106 include information describing functional elements that may be implemented by (e.g., performed by) the logic circuitry 2108. The logic circuitry 2108 is adapted to implement (e.g., perform) the functional elements described by the machine-executable code 2106. The device 2100, when executing the functional elements described by the machine-executable code 2106, should be considered as special purpose hardware configured for carrying out functional elements disclosed herein. In some embodiments, the processors 2102 may be configured to perform the functional elements described by the machine-executable code 2106 sequentially, concurrently (e.g., on one or more different hardware platforms), or in one or more parallel process streams.

When implemented by logic circuitry 2108 of the processors 2102, the machine-executable code 2106 is configured to adapt the processors 2102 to perform operations of embodiments disclosed herein. For example, the machine-executable code 2106 may be configured to adapt the processors 2102 to perform at least a portion or a totality of the method 1900 of FIG. 19 and method 2000 of FIG. 20.

The processors 2102 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein. A general-purpose computer including a processor is considered a special-purpose computer while the general-purpose computer is configured to execute computing instructions (e.g., software code) related to embodiments of the present disclosure. It is noted that a general-purpose processor (may also be referred to herein as a host processor or simply a host) may be a microprocessor, but in the alternative, the processors 2102 may include any conventional processor, controller, microcontroller, or state machine. The processors 2102 may also be implemented as a combination of computing devices, such as a combination of a DSP and a microprocessor, a plurality of microprocessors, one or more microprocessors in conjunction with a DSP core, or any other such configuration.

In some embodiments, the storage 2104 includes volatile data storage (e.g., random-access memory (RAM)), non-volatile data storage (e.g., Flash memory, a hard disc drive, a solid state drive, erasable programmable read-only memory (EPROM), etc.). In some embodiments the processors 2102 and the storage 2104 may be implemented into a single device (e.g., a semiconductor device product, a system on chip (SOC), etc.). In some embodiments the processors 2102 and the storage 2104 may be implemented into separate devices.

In some embodiments, the machine-executable code 2106 may include computer-readable instructions (e.g., software code, firmware code). By way of example, the computer-readable instructions may be stored by the storage 2104, accessed directly by the processors 2102, and executed by the processors 2102 using at least the logic circuitry 2108. Also by way of example, the computer-readable instructions may be stored on the storage 2104, transmitted to a memory device (not shown) for execution, and executed by the processors 2102 using at least the logic circuitry 2108. Accordingly, in some embodiments the logic circuitry 2108 includes electrically configurable logic circuitry.

In some embodiments, the machine-executable code 2106 may describe hardware (e.g., circuitry) to be implemented in the logic circuitry 2108 to perform the functional elements. This hardware may be described at any of a variety of levels of abstraction, from low-level transistor layouts to high-level description languages. At a high-level of abstraction, a hardware description language (HDL) such as an Institute of Electrical and Electronics Engineers (IEEE) Standard hardware description language (HDL) may be used. By way of example, VERILOG®, SYSTEMVERILOG® or very large scale integration (VLSI) hardware description language (VHDL®) may be used.

HDL descriptions may be converted into descriptions at any of numerous other levels of abstraction as desired. As an example, a high-level description can be converted to a logic-level description such as a register-transfer language (RTL), a gate-level (GL) description, a layout-level description, or a mask-level description. As an example, micro-operations to be performed by hardware logic circuits (e.g., gates, flip-flops, registers) of the logic circuitry 2108 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some embodiments the machine-executable code 2106 may include an HDL, an RTL, a GL description, a mask level description, other hardware description, or any combination thereof.

In embodiments where the machine-executable code 2106 includes a hardware description (at any level of abstraction), a system (not shown, but including the storage 2104) may be configured to implement the hardware description described by the machine-executable code 2106. By way of example, the processors 2102 may include a programmable logic device (e.g., an FPGA or a PLC) and the logic circuitry 2108 may be electrically controlled to implement circuitry corresponding to the hardware description into the logic circuitry 2108. Also by way of example, the logic circuitry 2108 may include hard-wired logic manufactured by a manufacturing system (not shown, but including the storage 2104) according to the hardware description of the machine-executable code 2106.

Regardless of whether the machine-executable code 2106 includes computer-readable instructions or a hardware description, the logic circuitry 2108 is adapted to perform the functional elements described by the machine-executable code 2106 when implementing the functional elements of the machine-executable code 2106. It is noted that although a hardware description may not directly describe functional elements, a hardware description indirectly describes functional elements that the hardware elements described by the hardware description are capable of performing.

As used in the present disclosure, the terms “module” or “component” may refer to specific hardware implementations configured to perform the actions of the module or component and/or software objects or software routines that may be stored on and/or executed by general purpose hardware (e.g., computer-readable media, processing devices, etc.) of the computing system. In some embodiments, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different sub-combinations of some of the elements. For example, the phrase “A, B, C, D, or combinations thereof” may refer to any one of A, B, C, or D; the combination of each of A, B, C, and D; and any sub-combination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting embodiments of the disclosure may include:

Embodiment 1: A method of analyzing changes that occur over time in a battery, the method comprising: defining an electrode of a battery; obtaining an expression for discrete interactions between the electrode and one or more of a solvent, a salt component, and an event that affects the battery; modeling the discrete interactions between the electrode and the one or more of the solvent, the salt component, and the event; and obtaining, based on the modeling of the discrete interactions, an aging profile indicative of changes in the battery resulting from the discrete interactions.

Embodiment 2: The method according to Embodiment 1, further comprising: defining an alternative electrode of the battery; modeling alternative discrete interactions between the alternative electrode and the one or more of the solvent, the salt component, and the event; obtaining, based on the modeling of the alternative discrete interactions, an alternative aging profile indicative of changes in the battery resulting from the alternative discrete interactions; and comparing the aging profile with the alternative aging profile.

Embodiment 3: The method according to any of Embodiments 1 and 2, further comprising designing another battery based on the comparison between the aging profile and the alternative aging profile.

Embodiment 4: The method according to any of Embodiments 1 through 3, further comprising: obtaining an alternative expression for alternative discrete interactions between the electrode and one or more of an alternative solvent, an alternative salt component, and an alternative event that affects the battery; modeling alternative discrete interactions between the electrode and the one or more of the alternative solvent, the alternative salt component, and the alternative event; obtaining, based on the modeling of the alternative discrete interactions, an alternative aging profile indicative of changes in the battery resulting from the alternative discrete interactions; and comparing the aging profile with the alternative aging profile.

Embodiment 5: The method according to any of Embodiments 1 through 4, further comprising designing another battery based on the comparison between the aging profile and the alternative aging profile.

Embodiment 6: The method according to any of Embodiments 1 through 5, wherein the expression for the discrete interactions includes a factor that influences the discrete interactions; the method further comprising: based on a first factor: modeling the discrete interactions and obtaining a first aging profile; based on a second factor: modeling the discrete interactions and obtaining a second aging profile; and comparing the first aging profile to the second aging profile.

Embodiment 7: The method according to any of Embodiments 1 through 6, further comprising determining to use or manage the battery according to the first factor based on the comparison between the first aging profile and the second aging profile.

Embodiment 8: The method according to any of Embodiments 1 through 7, further comprising providing instructions to use or manage the battery according to the first factor based on the comparison between the first aging profile and the second aging profile.

Embodiment 9: The method according to any of Embodiments 1 through 8, wherein the expression for the discrete interactions includes a factor that influences the discrete interactions; the method further comprising: obtaining a usage factor indicative of conditions of the battery during a period of use; and based on the usage factor: modeling the discrete interactions and obtaining a usage aging profile.

Embodiment 10: The method according to any of Embodiments 1 through 9, further comprising one or more of: based on the usage aging profile, predicting a remaining lifespan of the battery under the conditions; and based on the usage aging profile, predicting the remaining lifespan of the battery under different conditions.

Embodiment 11: The method according to any of Embodiments 1 through 10, wherein defining the electrode comprises defining one or more of: available surface sites of the electrode, molar concentration of available surface sites of the electrode, reactivity of an electrode material, and a number of deactivated sites of the electrode.

Embodiment 12: The method according to any of Embodiments 1 through 11, further comprising defining one or more of the solvent or the salt component.

Embodiment 13: The method according to any of Embodiments 1 through 12, wherein the expression is a sigmoid-based rate expression.

Embodiment 14: One or more non-transitory computer-readable media that include instructions, that when executed by one or more processors, are configured to cause the one or more processors to perform operations, the operations comprising: defining an electrode of a battery; obtaining an expression for discrete interactions between the electrode and one or more of a solvent, a salt component, and an event that affects the battery; modeling the discrete interactions between the electrode and the one or more of the solvent, the salt component, and the event; and obtaining, based on the modeling of the discrete interactions, an aging profile indicative of changes in the battery resulting from the discrete interactions.

Embodiment 15: A method of analyzing changes that occur over time in a system, the method comprising: defining a population of a system; obtaining an expression for discrete interactions between the population and one or both of an agent and an event; modeling the discrete interactions between the population and the one or both of the agent and the event; and obtaining, based on the modeling of the discrete interactions, an aging profile indicative of changes in the population resulting from the discrete interactions.

Embodiment 16: The method according to Embodiment 15, wherein the population comprises a first population, wherein the expression comprises a first expression, wherein the discrete interactions comprise first discrete interactions, and wherein the aging profile comprises a first aging profile, the method further comprising: defining a second population of the system; obtaining a second expression for second discrete interactions between the second population and the one or both of the agent and the event; modeling the second discrete interactions between the second population and the one or both of the agent and the event; and obtaining, based on the modeling of the second discrete interactions, a second aging profile indicative of changes in the second population resulting from the second discrete interactions.

Embodiment 17: The method according to any of Embodiments 15 and 16, further comprising developing an aggregate aging profile for the system based on the first aging profile and the second aging profile.

Embodiment 18: The method according to any of Embodiments 15 through 17, further comprising designing another system based on the first aging profile and the second aging profile.

Embodiment 19: The method according to any of Embodiments 15 through 18, further comprising determining to use or manage the system according to the first aging profile and the second aging profile.

Embodiment 20: The method according to any of Embodiments 15 through 19, wherein the system comprises a battery, wherein the first population corresponds to first molecules of an electrode of the battery, wherein the second population corresponds to second molecules of the electrode of the battery, and wherein the agent comprises one or more of a solvent or a salt component.

What is claimed is:

1. A method of analyzing changes that occur over time in a battery, the method comprising:
defining an electrode of a battery;
obtaining an expression for discrete interactions between the electrode and one or more of a solvent, a salt component, and an event that affects the battery;
modeling the discrete interactions between the electrode and the one or more of the solvent, the salt component, and the event; and
obtaining, based on the modeling of the discrete interactions, an aging profile indicative of changes in the battery resulting from the discrete interactions.

2. The method of claim 1, further comprising:
defining an alternative electrode of the battery;
modeling alternative discrete interactions between the alternative electrode and the one or more of the solvent, the salt component, and the event;
obtaining, based on the modeling of the alternative discrete interactions, an alternative aging profile indicative of changes in the battery resulting from the alternative discrete interactions; and
comparing the aging profile with the alternative aging profile.

3. The method of claim 2, further comprising designing another battery based on the comparison between the aging profile and the alternative aging profile.

4. The method of claim 1, further comprising:
obtaining an alternative expression for alternative discrete interactions between the electrode and one or more of an alternative solvent, an alternative salt component, and an alternative event that affects the battery;
modeling alternative discrete interactions between the electrode and the one or more of the alternative solvent, the alternative salt component, and the alternative event;
obtaining, based on the modeling of the alternative discrete interactions, an alternative aging profile indicative of changes in the battery resulting from the alternative discrete interactions; and
comparing the aging profile with the alternative aging profile.

5. The method of claim 4, further comprising designing another battery based on the comparison between the aging profile and the alternative aging profile.

6. The method of claim 1, wherein the expression for the discrete interactions includes a factor that influences the discrete interactions; the method further comprising:
based on a first factor: modeling the discrete interactions and obtaining a first aging profile;
based on a second factor: modeling the discrete interactions and obtaining a second aging profile;
and comparing the first aging profile to the second aging profile.

7. The method of claim 6, further comprising determining to use or manage the battery according to the first factor based on the comparison between the first aging profile and the second aging profile.

8. The method of claim 6, further comprising providing instructions to use or manage the battery according to the first factor based on the comparison between the first aging profile and the second aging profile.

9. The method of claim 1, wherein the expression for the discrete interactions includes a factor that influences the discrete interactions; the method further comprising:
obtaining a usage factor indicative of conditions of the battery during a period of use; and
based on the usage factor: modeling the discrete interactions and obtaining a usage aging profile.

10. The method of claim 9, further comprising one or more of:
based on the usage aging profile, predicting a remaining lifespan of the battery under the conditions; and
based on the usage aging profile, predicting the remaining lifespan of the battery under different conditions.

11. The method of claim 1, wherein defining the electrode comprises defining one or more of:
available surface sites of the electrode,
molar concentration of available surface sites of the electrode,
reactivity of an electrode material, and
a number of deactivated sites of the electrode.

12. The method of claim 1, further comprising defining one or more of the solvent or the salt component.

13. The method of claim 1, wherein the expression is a sigmoid-based rate expression.

14. One or more non-transitory computer-readable media that include instructions, that when executed by one or more processors, are configured to cause the one or more processors to perform operations, the operations comprising:
defining an electrode of a battery;
obtaining an expression for discrete interactions between the electrode and one or more of a solvent, a salt component, and an event that affects the battery;
modeling the discrete interactions between the electrode and the one or more of the solvent, the salt component, and the event; and
obtaining, based on the modeling of the discrete interactions, an aging profile indicative of changes in the battery resulting from the discrete interactions.

15. A method of analyzing changes that occur over time in a system, the method comprising:
defining a population of a system;
obtaining an expression for discrete interactions between the population and one or both of an agent and an event;
modeling the discrete interactions between the population and the one or both of the agent and the event; and
obtaining, based on the modeling of the discrete interactions, an aging profile indicative of changes in the population resulting from the discrete interactions.

16. The method of claim 15, wherein the population comprises a first population, wherein the expression comprises a first expression, wherein the discrete interactions comprise first discrete interactions, and wherein the aging profile comprises a first aging profile, the method further comprising:
defining a second population of the system;
obtaining a second expression for second discrete interactions between the second population and the one or both of the agent and the event;
modeling the second discrete interactions between the second population and the one or both of the agent and the event; and
obtaining, based on the modeling of the second discrete interactions, a second aging profile indicative of changes in the second population resulting from the second discrete interactions.

17. The method of claim 16, further comprising developing an aggregate aging profile for the system based on the first aging profile and the second aging profile.

18. The method of claim 16, further comprising designing another system based on the first aging profile and the second aging profile.

19. The method of claim 16, further comprising determining to use or manage the system according to the first aging profile and the second aging profile.

20. The method of claim 16, wherein the system comprises a battery, wherein the first population corresponds to first molecules of an electrode of the battery, wherein the second population corresponds to second molecules of the electrode of the battery, and wherein the agent comprises one or more of a solvent or a salt component.
